(19) United States
(12) Patent Application Publication
(10) Pub. No.: US 2026/0250177 A1
(43) Pub. Date: Aug. 27, 2026

(54) APPARATUS FOR MANUFACTURING COVER WINDOW, METHOD FOR MANUFACTURING COVER WINDOW, AND ELECTRONIC DEVICE INCLUDING COVER WINDOW

(71) Applicant: Samsung Display Co., Ltd., Yongin-si (KR)

(72) Inventors: Woo Hyun JUNG, Yongin-si (KR); Konstantin MISHCHIK, Yongin-si (KR); Sung Gyu PARK, Yongin-si (KR); Kyung Han YOO, Yongin-si (KR); Hyung Sik KIM, Yongin-si (KR); Cheol Lae ROH, Yongin-si (KR); Je Kil RYU, Yongin-si (KR); Seong Ho JEONG, Yongin-si (KR)

(73) Assignee: Samsung Display Co., Ltd., Yongin-si (KR)

(21) Appl. No.: 19/327,612

(22) Filed: Sep. 12, 2025

(30) Foreign Application Priority Data
Feb. 25, 2025 (KR) 10-2025-0024157

(51) Int. Cl. C03B 33/10; B23K 26/06; B23K 26/066; B23K 26/067; B23K 101/36; B23K 103/00; C03B 33/023; G06F 1/16; H10H 29/01; H10H 29/85; H10K 59/12; H10K 59/80; H10K 71/00; H10K 77/10

(52) U.S. Cl. CPC C03B 33/102; B23K 26/0648; B23K 26/0652; B23K 26/066; B23K 26/067; C03B 33/023; H10H 29/036; H10K 71/851; B23K 2101/36; B23K 2103/54; G06F 1/1656; H10H 29/8508; H10K 59/1201; H10K 59/871; H10K 77/10

(57) ABSTRACT

Provided are apparatuses for manufacturing cover window, methods for manufacturing cover window, and electronic devices including cover window. An apparatus for manufacturing a cover window includes a light source outputting a raw laser beam, a beam splitter splitting the raw laser beam into a main beam and at least one sub-beam, a first phase mask diffracting the main beam to convert the main beam into a straight-line beam, a second phase mask diffracting the sub-beam to convert the sub-beam into a dotted-line beam including a plurality of spot beams, a beam combiner combining the main beam and the sub-beam to form a single combined beam, and an objective lens focusing the combined beam onto a focal plane, wherein the beam splitter sets extension directions of a polarization axis of the main beam and a polarization axis of the sub-beam to be different from each other.

### CROSS-REFERENCE TO RELATED APPLICATION

This application claims priority from Korean Patent Application No. 10-2025-0024157 filed on Feb. 25, 2025 in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to apparatuses for manufacturing a cover window, methods for manufacturing a cover window, and/or electronic devices including a cover window.

### 2. Description of the Related Art

With the advance of information-oriented society, on the demand for display devices to display images in various ways is increasing. The display device may be a display device such as a liquid crystal display, a field emission display or a light emitting display. The light emitting display may include an organic light emitting display device including an organic light emitting diode as a light emitting element or an inorganic light emitting display device including an inorganic light emitting diode as a light emitting element.

To improve the mechanical strength of a cover window included in or attached to the display device, a process of machining the side surface of the cover window using a computer numerical control (CNC) polishing device or the like and performing wet etching is carried out. However, during the CNC process, defects such as wedges and/or chipping may occur on the side surface of the cover window, resulting in an increase in the manufacturing cost of the cover window.

### SUMMARY

Some example embodiments of the present disclosure may provide apparatuses for manufacturing a cover window and/or methods for manufacturing a cover window, which can reduce manufacturing cost without substantially degrading mechanical strength.

Some example embodiments of the present disclosure may provide electronic devices including a cover window, which can reduce manufacturing cost without substantially degrading mechanical strength.

However, example embodiments of the present disclosure are not restricted to those set forth herein. The above and other example embodiments of the present disclosure will become more apparent to one of ordinary skill in the art to which the present disclosure pertains by referencing the detailed description of the present disclosure given below.

According to an example embodiment of the present disclosure, an apparatus for manufacturing a cover window may include a light source configured to output a raw laser beam, a beam splitter configured to split the raw laser beam into a main beam and at least one sub-beam, a first phase mask configured to diffract the main beam to convert the main beam into a straight-line beam, a second phase mask configured to diffract the sub-beam to convert the sub-beam into a dotted-line beam including a plurality of spot beams, a beam combiner configured to combine the main beam and the sub-beam to form a single combined beam, and an objective lens configured to focus the combined beam onto a focal plane, wherein the beam splitter is configured to set extension directions of a polarization axis of the main beam and a polarization axis of the sub-beam to be different from each other.

In an example embodiment, the polarization axis of the main beam and the polarization axis of the sub-beam may be orthogonal to each other.

In an example embodiment, the apparatus may further comprise an optical delay being either between the beam splitter and the first phase mask or between the beam splitter and the second phase mask, wherein the optical delay is configured to delay a time at which either the main beam or the sub-beam arrives at the beam combiner.

In an example embodiment, a time delay range of the optical delay may be 1 ps to 10 ps.

In an example embodiment, the first phase mask may have a shape in which concentric circles having the same single center are arranged radially, and the second phase mask may have a shape in which concentric circles having at least two different centers are arranged radially.

In an example embodiment, the at least two centers of the second phase mask may include a first center and a second center, and a first group of the concentric circles having the first center and a second group of the concentric circles having the second center may be symmetric to each other with respect to a first straight line extending in one direction.

In an example embodiment, the main beam and the sub-beam converted by the first phase mask and the second phase mask, respectively, may have a Bessel beam shape.

In an example embodiment, the raw laser beam may be a Gaussian beam.

In an example embodiment, a numerical aperture of the objective lens may be 0.4 or more.

In an example embodiment, in the focal plane, the main beam and the sub-beam may be spaced apart in a first direction.

In an example embodiment, in the focal plane, the main beam and the sub-beam may extend in a second direction different from the first direction.

In an example embodiment, the sub-beam may extend in the second direction and may include a plurality of spot beams spaced apart from each other in the second direction.

In an example embodiment, in the second direction, a depth of focus of the main beam may be greater than a depth of focus of each of the plurality of spot beams.

In an example embodiment, a width of the main beam in the first direction and a width of the sub-beam in the first direction may be 1 μm or less.

In an example embodiment, an aspect ratio of the sub-beam may be defined as a depth of focus of the sub-beam in the second direction with respect to a width of the sub-beam in the first direction, and the aspect ratio of the sub-beam may be 20 or more.

In an example embodiment, a beam intensity of the sub-beam may be 30% to 80% of a beam intensity of the main beam.

According to an example embodiment of the present disclosure, a method for manufacturing a cover window may include forming a sketch line for forming a cover window by irradiating a laser beam onto a mother glass, and etching the cover window using an etchant, wherein the sketch line includes a first sketch line and a second sketch line positioned inside the first sketch line, the cover window is separated from the mother glass by the first sketch line, and the etchant penetrates in an inward direction of the cover window through the second sketch line.

In an example embodiment, the first sketch line may penetrate the mother glass in a thickness direction, the second sketch line may extend from top and bottom surfaces of the mother glass in an inward direction of the mother glass, and a length of the second sketch line may be less than a thickness of the mother glass.

In an example embodiment, the sketch line may include a third sketch line positioned inward from the second sketch line, and a length of the third sketch line may be less than a length of the second sketch line.

According to an example embodiment of the present disclosure, an electronic device may include a display device including a cover window manufactured by the aforementioned cover window manufacturing apparatus, and a display panel located under the cover window, a processor configured to provide a driving signal to the display device, and a power module configured to supply power to the display device.

In accordance with the cover window manufacturing apparatus and/or the cover window manufacturing method according to some example embodiments of the present disclosure, it is possible to manufacture a cover window that can reduce manufacturing cost without substantially degrading mechanical strength.

The electronic device according to some example embodiments of the present disclosure may include a cover window that can reduce manufacturing cost without substantially degrading mechanical strength.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic perspective view showing an electronic device according to an example embodiment;

FIG. 2 is a perspective view showing a display device included in an electronic device according to an example embodiment;

FIG. 3 is a block diagram illustrating a display device according to an example embodiment;

FIG. 4 is an equivalent circuit diagram illustrating a pixel of a display device according to an example embodiment;

FIGS. 5 and 6 are cross-sectional views illustrating a display device according to some example embodiments;

FIG. 7 is a cross-sectional view illustrating a cross-section of a display area of a display device according to an example embodiment;

FIG. 8 is a front perspective view showing a cover window according to an example embodiment;

FIG. 9 is a rear perspective view showing a cover window according to an example embodiment;

FIG. 10 is a plan view showing a cover window according to an example embodiment;

FIG. 11 is a cross-sectional view taken along line X1-X1′ of FIG. 10;

FIG. 12 is a flowchart showing a method for manufacturing a cover window according to an example embodiment;

FIGS. 13 and 14 are perspective views showing operation S110 of FIG. 12;

FIG. 15 is a cross-sectional view showing operation S120 of FIG. 12;

FIGS. 16 and 17 are cross-sectional views showing operation S110 of FIG. 12;

FIG. 18 is an enlarged view of area A of FIG. 15;

FIGS. 19 and 20 are cross-sectional views illustrating operation S110 of a cover window manufacturing method according to an example embodiment;

FIG. 21 is a cross-sectional view illustrating operation S120 of a cover window manufacturing method according to an example embodiment;

FIG. 22 is a schematic side view illustrating a cover window manufacturing apparatus according to an example embodiment;

FIG. 23 is a plan view showing a diffraction pattern of a first phase mask in an XY plane;

FIG. 24 is a plan view showing a diffraction pattern of a second phase mask in an XY plane;

FIG. 25A is a photograph illustrating a two-dimensional shape of a main beam and sub-beams in an XY plane formed by a cover window manufacturing apparatus according to an example embodiment;

FIG. 25B is a photograph illustrating a two-dimensional shape of a main beam and sub-beams in an XY plane formed by a cover window manufacturing apparatus according to a comparative example;

FIG. 26A is a photograph illustrating a two-dimensional shape of a main beam and sub-beams in a YZ plane formed by a cover window manufacturing apparatus according to an example embodiment;

FIG. 26B is a photograph illustrating a two-dimensional shape of a main beam and sub-beams in a YZ plane formed by a cover window manufacturing apparatus according to a comparative example;

FIG. 27 is a graph illustrating the beam intensities of a main beam and sub-beams according to a Z-axis position;

FIG. 28 is a schematic diagram illustrating a sketch line formed on a mother glass by a main beam and sub-beams;

FIG. 29 is a block diagram of an electronic device according to an example embodiment; and

FIG. 30 is schematic views of electronic devices according to various example embodiments.

### DETAILED DESCRIPTION

The inventive concepts will now be described more fully hereinafter with reference to the accompanying drawings, in which some example embodiments of the inventive concepts are shown. The inventive concepts may, however, be embodied in different forms and should not be construed as limited to the example embodiments set forth herein. Rather, these example embodiments are provided so that this disclosure will be thorough and complete, and will filly convey the scope of the inventive concepts to those skilled in the art.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

It will also be understood that when a layer is referred to as being “on” another layer or substrate, it can be directly on the other layer or substrate, or intervening layers may also be present. The same reference numbers indicate the same components throughout the specification.

Hereinafter, some example embodiments of the present disclosure will be described in detail with reference to the accompanying drawings.

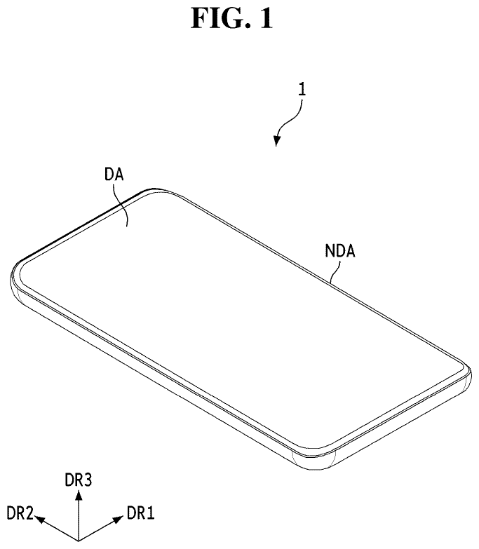

FIG. 1 is a schematic perspective view showing an electronic device according to an example embodiment.

Referring to FIG. 1, an electronic device 1 displays a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

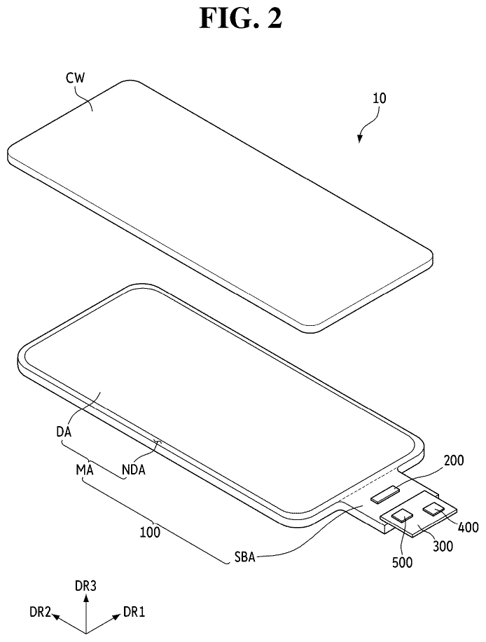

The electronic device 1 may include a display device 10 (see FIG. 2) providing a display screen. Examples of the display device may include an inorganic light emitting diode display device, an organic light emitting display device, a quantum dot light emitting display device, a plasma display device and a field emission display device. In the following description, a case where an organic light emitting diode display device is applied as a display device will be described as an example, but example embodiments of the present disclosure are not limited thereto. In some example embodiments, other display devices may be applied within the same scope of technical spirit.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes or a circular shape. The shape of a display area DA of the electronic device 1 may also be similar to the overall shape of the electronic device 1. FIG. 1 illustrates the electronic device 1 having a rectangular shape in which a length in a second direction DR2 is longer than a length in a first direction DR1.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, a perpendicular direction orthogonal to the first direction DR1 and the second direction DR2. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The electronic device 1 may include the display area DA and a non-display area NDA. The display area DA is an area where a screen can be displayed, and the non-display area NDA is an area where a screen is not displayed. The display area DA may also be referred to as an active region, and the non-display area NDA may also be referred to as a non-active region. The display area DA may substantially occupy the center of the electronic device 1. In other words, the display area DA may occupy the central area of the electronic device 1 and may be surrounded by the non-display area NDA.

FIG. 2 is a perspective view showing a display device included in an electronic device according to an example embodiment.

Referring to FIG. 2 in addition to FIG. 1, the electronic device 1 according to an example embodiment may include the display device 10. The display device 10 may provide a screen displayed by the electronic device 1. The display device 10 may have a planar shape similar to the shape of the electronic device 1. For example, the display device 10 may have a shape similar to a rectangular shape having a short side (e.g., a relatively short side) in a first direction DR1 and a long side (e.g., a relatively long side) in the second direction DR2. The edge where the short side in the first direction DR1 and the long side in the second direction DR2 meet may be rounded to have a curvature but is not limited thereto and may be formed at a right angle. The planar shape of the display device 10 is not limited to a quadrilateral shape and may be formed in a shape similar to another polygonal shape, a circular shape, or elliptical shape.

The display device 10 may include a cover window CW, a display panel 100, a driving circuit 200, a circuit board 300, a touch driver 400, and a power supply unit (or alternatively, power supply circuitry) 500.

The display panel 100 may include a main region MA and a sub-region SBA.

The main region MA may include the display area DA including pixels displaying an image and the non-display area NDA located around the display area DA. The display area DA may be located in the center of the main region MA, and the non-display area NDA may surround the display area DA. The display area DA may emit light from a plurality of emission areas or a plurality of opening areas. For example, the display panel 100 may include a pixel circuit including switching elements, a pixel defining film defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a gate driver that supplies gate signals to the gate lines, and fan-out lines that connect the driving circuit 200 to the display area DA.

The sub-region SBA may be a region extending from one side of the main region MA. The sub-region SBA may include a flexible material which can be bent, folded or rolled. For example, when the sub-region SBA is bent, the sub-region SBA may overlap the main region MA in a thickness direction (e.g., the third direction DR3). The sub-region SBA may include the driving circuit 200 and a pad portion connected to the circuit board 300.

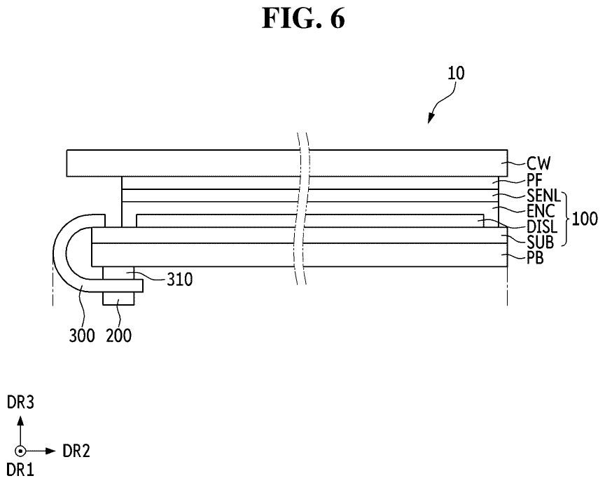

In another example embodiment, the sub-region SBA may be omitted, and the driving circuit 200 and the pad portion may be located in the non-display area NDA. In this case, as shown in FIG. 6 to be described later, the circuit board 300 may be bent instead of the sub-region SBA.

The driving circuit 200 may output signals and voltages for driving the display panel 100. The driving circuit 200 may supply data voltages to data lines. The driving circuit 200 may supply a power voltage to the power line and may supply a gate control signal to the gate driver.

The driving circuit 200 may be formed as an integrated circuit (IC) and mounted on the display panel 100 by a chip on glass (COG) method, a chip on plastic (COP) method, or an ultrasonic bonding method. For example, the driving circuit 200 may be located in the sub-region SBA and may overlap the main region MA in the thickness direction by bending of the sub-region SBA. For another example, the driving circuit 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit (or alternatively, a touch sensor) of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a selected frequency. The touch driver 400 may calculate whether an input is made and input coordinates based on an amount of change in capacitance between the plurality of touch electrodes. The touch driver 400 may be formed as an integrated circuit (IC).

The power supply unit 500 may be located on the circuit board 300 to supply a power voltage to the driving circuit 200 and the display panel 100. The power supply unit 500 may generate a driving voltage to supply it to a driving voltage line and may generate a common voltage to supply it to a common electrode. For example, the driving voltage may be a relatively high potential voltage for driving the light emitting element, and the common voltage may be a relatively low potential voltage for driving the light emitting element. The power supply unit 500 may generate an initialization voltage to supply it to an initialization voltage line, generate a reference voltage to supply it to a reference voltage line, generate a bias voltage to supply it to a bias voltage line, and generate a reset voltage to supply it to a reset voltage line.

The cover window CW may be positioned on the front surface of the display panel 100 to protect the front surface of the display panel 100 from an external impact. The cover window CW may include a transparent material. For example, the cover window CW may be glass. In this case, in order for the cover window CW to have a foldable and flexible characteristic, the cover window CW may be ultra-thin glass (UTG) having a thickness of approximately 500 μm or less.

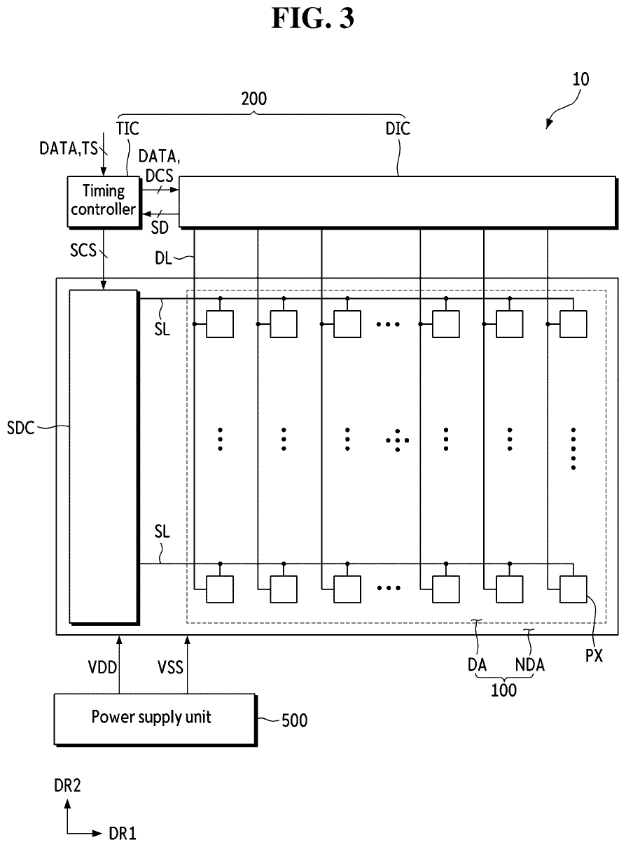

FIG. 3 is a block diagram illustrating a display device according to an example embodiment.

Referring to FIG. 3, the display device 10 according to an example embodiment may include the display panel 100, a scan driving circuit unit SDC, the driving circuit 200, and the power supply unit 500.

The display panel 100 includes data lines DL, scan lines SL and pixels PX. The scan lines SL may extend in the first direction DR1 and may be arranged in the second direction DR2. The data lines DL may extend in the second direction DR2 and may be arranged along the first direction DR1.

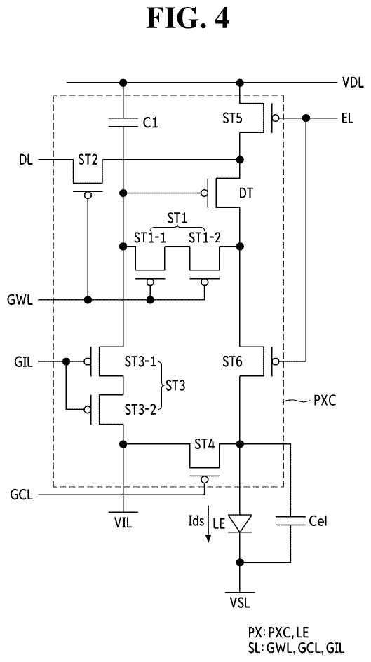

Each of the pixels PX may be connected to at least one of the data lines DL and at least one of the scan lines SL. As shown in FIG. 4, each of the pixels PX may include a light emitting element LE (see FIG. 4) and a pixel circuit portion PXC (see FIG. 4) including a plurality of transistors for supplying a driving current to the light emitting element LE (see FIG. 4). A detailed description of the pixels PX will be given later with reference to FIG. 4.

The scan driving circuit unit SDC and the driving circuit 200 may be referred to as a display panel driver. The driving circuit 200 may include a timing control circuit unit (or alternatively, a timing control circuitry) TIC and a data driving circuit unit (or alternatively, a data driving circuitry) DIC.

The scan driving circuit unit SDC is connected to the scan lines SL and applies scan signals to the scan lines SL. The scan driving circuit unit SDC may generate scan signals according to a scan timing control signal SCS inputted from the timing control circuit unit TIC and output the scan signals to the scan lines SL.

The scan driving circuit unit SDC may include a plurality of transistors. In some example embodiments, the scan driving circuit unit SDC may be positioned in the non-display area NDA located on the left side of the display panel 100. However, example embodiments of the present disclosure are not limited thereto, and the scan driving circuit unit SDC may be positioned in the non-display area NDA located on the right side or on both the left and right sides of the display panel 100.

The data driving circuit unit DIC is connected to the data lines DL and supplies data voltages to the data lines DL. The data driving circuit unit DIC may receive digital video data DATA and a data timing control signal DCS from the timing control circuit unit TIC. The data driving circuit unit DIC may convert the digital video data DATA into data voltages according to the data timing control signal DCS and output the data voltages to the data lines DL.

The timing control circuit unit TIC may receive the digital video data DATA and timing signals TS. The timing signals TS may include a vertical synchronization signal, a horizontal synchronization signal, a data enable signal, a clock signal such as a dot clock, and the like.

The timing control circuit unit TIC may generate control signals for controlling the operation timings of the data driving circuit unit DIC and the scan driving circuit unit SDC. The control signals may include the data timing control signal DCS for controlling the operation timing of the data driving circuit unit DIC, and the scan timing control signal SCS for controlling the operation timing of the scan driving circuit unit SDC.

The timing control circuit unit TIC may output the digital video data DATA and the data timing control signal DCS to the data driving circuit unit DIC and output the scan timing control signal SCS to the scan driving circuit unit SDC.

The power supply unit 500 may generate a first power voltage VSS corresponding to a relatively low potential voltage and a second power voltage VDD corresponding to a relatively high potential voltage from a main power source applied from the outside. In addition, the power supply unit 500 may supply various driving voltages to the data driving circuit unit DIC, the scan driving circuit unit SDC, and the timing control circuit unit TIC.

FIG. 4 is an equivalent circuit diagram illustrating a pixel of a display device according to an example embodiment.

Referring to FIG. 4, the pixel PX according to an example embodiment may include the pixel circuit portion PXC and the light emitting element LE.

The light emitting element LE emits light according to a driving current Ids. The emission amount of the light emitting element LE may be proportional to the driving current Ids.

The light emitting element LE may be an organic light emitting element including an anode electrode, a cathode electrode, and an organic light emitting layer located between the anode electrode and the cathode electrode. In some example embodiments, the light emitting element LE may be an inorganic light emitting element including an anode electrode, a cathode electrode, and an inorganic semiconductor located between the anode electrode and the cathode electrode.

The anode electrode of the light emitting element LE may be connected to a first electrode of the fourth transistor ST4 and a second electrode of the sixth transistor ST6, and the cathode electrode thereof may be connected to a first power line VSL. A parasitic capacitance Cel may be formed between the anode electrode and the cathode electrode of the light emitting element LE.

The pixel circuit unit PXC includes the driving transistor DT, the switch elements, and a capacitor C1. The switch elements include the first to sixth transistors ST1, ST2, ST3, ST4, ST5, and ST6.

The driving transistor DT includes a gate electrode, a first electrode, and a second electrode. The driving transistor DT controls a driving current flowing between the first electrode and the second electrode according to a data voltage applied to the gate electrode.

The capacitor C1 is formed between the second electrode of the driving transistor DT and the first power line VDL. One electrode of the capacitor C1 may be connected to the second electrode of the driving transistor DT, and the other electrode of the capacitor C1 may be connected to the first power line VDL.

When the first electrode of each of the driving transistor DT and the first to sixth transistors ST1 to ST6 is a source electrode, the second electrode thereof may be a drain electrode. Alternatively, when the first electrode of each of the driving transistor DT and the first to sixth transistors ST1 to ST6 is a drain electrode, the second electrode thereof may be a source electrode.

An active layer of each of the driving transistor DT and the first to sixth transistors ST1 to ST6 may include any one of polysilicon, amorphous silicon, or an oxide semiconductor. When a semiconductor layer of each of the driving transistor DT and the first to sixth transistors ST1 to ST6 includes polysilicon, a process for forming the semiconductor layer may be a low temperature polysilicon (LTPS) process.

Further, in FIG. 4, the driving transistor DT and the first to sixth transistors ST1 to ST6 have been described as being formed as p-type metal oxide semiconductor field effect transistors (MOSFETs), but example embodiments of the present disclosure are not limited thereto. In some example embodiments, the driving transistor DT and the first to sixth transistors ST1 to ST6 may be formed as n-type MOSFETs.

Furthermore, the first power voltage VSS of the first power line VSL, the second power voltage VDD of the second power line VDL, and a third power voltage (or initialization voltage) of a third power line VIL may be set in consideration of the characteristics of the driving transistor DT, the characteristics of the light emitting element LE, and the like.

The pixel PX according to example embodiments of the present disclosure are not limited to that shown in FIG. 4. The pixel PX according to some example embodiments of the present disclosure may have other known circuit structures that those skilled in the art may employ in addition to the embodiment illustrated in FIG. 4.

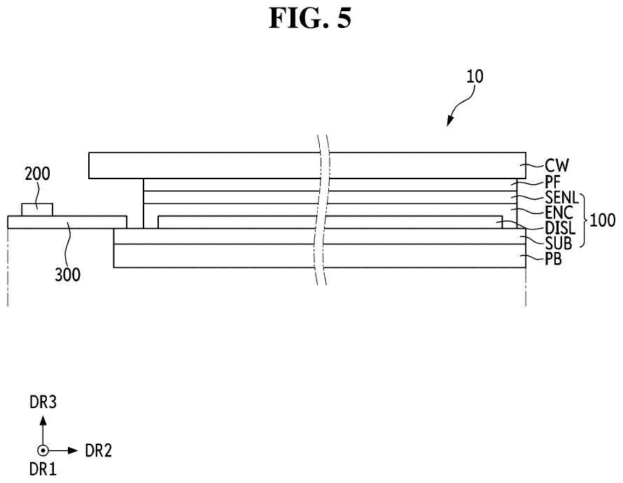

FIGS. 5 and 6 are cross-sectional views illustrating a display device according to some example embodiments. FIG. 5 illustrates a state in which the circuit board 300 is unfolded, and FIG. 6 illustrates a state in which the circuit board 300 is bent.

Referring to FIGS. 5 and 6, the display device 10 according to some example embodiments may include the display panel 100, a polarizing film PF, a cover window CW, and a panel lower cover PB. The display panel 100 may include a substrate SUB, a display layer DISL, an encapsulation layer ENC, and a sensor electrode layer SENL.

The substrate SUB may be a stretchable flexible substrate. The substrate SUB may include an insulating material. For example, the substrate SUB may include polymer resin such as acrylic resin, epoxy resin, phenolic resin, polyamide resin, or polyimide resin.

In another example embodiment, the substrate SUB may have a relatively hard material. For example, the substrate SUB may include glass. The substrate SUB may include ultra-thin glass (UTG) having a thickness of approximately 500 μm or less. For example, the thickness of the substrate SUB may be approximately 200 μm.

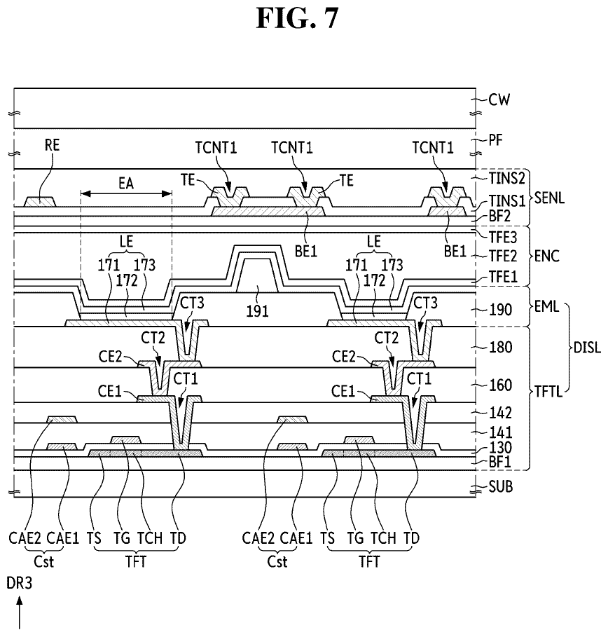

The display layer DISL may be located on the first surface of the substrate SUB. The display layer DISL may be a layer displaying an image. The display layer DISL may include a thin film transistor layer TFTL (see FIG. 7) in which thin film transistors are formed, and a light emitting element layer EML (see FIG. 7) in which light emitting elements emitting light are located in the emission areas.

In the display area DA of the display layer DISL, scan lines, data lines, power lines, or the like for the emission areas to emit light may be located. In the non-display area NDA of the display layer DISL, a scan driving circuit unit outputting scan signals to the scan lines, fan-out lines connecting the data lines and the driving circuit 200, and the like may be located.

The encapsulation layer ENC may be a layer for encapsulating the light emitting element layer EML of the display layer DISL to reduce or prevent permeation of oxygen or moisture into the light emitting element layer EML of the display layer DISL. The encapsulation layer ENC may be located on the display layer DISL. The encapsulation layer ENC may be located on the top surfaces and the side surfaces of the display layer DISL. The encapsulation layer ENC may be located to cover the display layer DISL.

The sensor electrode layer SENL may be located on the display layer DISL. The sensor electrode layer SENL may include sensor electrodes. The sensor electrode layer SENL may sense a user's touch using sensor electrodes.

The polarizing film PF may be positioned on the display panel 100 to reduce or prevent a decrease in the visibility of an image displayed on the display panel 100 due to external light being reflected from the display panel 100. The polarizing film PF may include a first base member, a linear polarization plate, a phase retardation film such as a quarter-wave plate (λ/4 plate), and a second base member. The first base member, the phase retardation film, the linear polarization plate, and the second base member of the polarizing film PF may be sequentially stacked on the display panel 100.

In another example embodiment, an optical layer including a color filter instead of the polarizing film PF may be positioned between the display panel 100 and the cover window CW. The optical layer may include a plurality of color filters to reduce or prevent a decrease in the visibility of an image displayed on the display panel 100 due to external light being reflected from the display panel 100.

The cover window CW may be located on the polarizing film PF. The cover window CW may be attached to the polarizing film PF by a transparent adhesive member such as an optically clear adhesive (OCA) film or an optically clear resin (OCR).

The panel lower cover PB may be located on a second surface of the substrate SUB of the display panel 100. The second surface of the substrate SUB may be a surface opposite to the first surface. The panel lower cover PB may be attached to the second surface of the substrate SUB of the display panel 100 through an adhesive member. The adhesive member may be a pressure sensitive adhesive (PSA).

The panel lower cover PB may include at least one of a light blocking member for absorbing light incident from the outside, a buffer member for absorbing an impact from the outside, or a heat dissipation member for efficiently dissipating heat from the display panel 100.

The light blocking member may be located under the display panel 100. The light blocking member blocks light transmission, thereby reducing or preventing components (e.g., a circuit board 300 and the like) located under the light blocking member from being viewed from the top of the display panel 100. The light blocking member may include a light absorbing material such as a black pigment, black dyes or the like.

The buffer member may be located under the light blocking member. The buffer member absorbs an external impact to reduce or prevent the display panel 100 from being damaged. The buffer member may be formed as a single layer or multiple layers. For example, the buffer member may include polymer resin such as polyurethane (PU), polycarbonate (PC), polypropylene (PP), or polyethylene (PE) or may include an elastic material such as a foamed sponge obtained from rubber, a urethane-based material, or an acrylic material.

The heat dissipation member may be located under the buffer member. The heat dissipation member may include a first heat dissipation layer containing graphite, carbon nanotubes or the like, and a second heat dissipation layer formed as a metal thin film containing, for example, copper, nickel, ferrite, or silver which can shield electromagnetic waves and has excellent or relatively great thermal conductivity.

The circuit board 300 may be bent toward the bottom of the display panel 100 as shown in FIG. 6. The circuit board 300 may be attached to the bottom surface of the panel lower cover PB by an adhesive member 310. The adhesive member 310 may be a pressure sensitive adhesive.

FIG. 7 is a cross-sectional view illustrating a cross-section of a display area of a display device according to an example embodiment.

Referring to FIG. 7, the display panel 100 according to an example embodiment may be an organic light emitting display panel having the light emitting element LE including an organic light emitting layer 172.

The substrate SUB has been described above with reference to FIGS. 5 and 6, and thus a description thereof will be omitted.

The display layer DISL may include the thin film transistor layer TFTL including a plurality of thin film transistors and the light emitting element layer EML including a plurality of light emitting elements.

The thin film transistor layer TFTL may include a first buffer film BF1, an active layer, a gate insulating film 130, a first gate metal layer, a first interlayer insulating film 141, a second gate metal layer, a second interlayer insulating film 142, a first data metal layer, a first organic film 160, a second data metal layer, and a second organic film 180. The thin film transistor layer TFTL may further include a thin film transistor TFT and a capacitor Cst.

A first buffer film BF1 may be located on the substrate SUB. The first buffer film BF1 may include an inorganic material such as a silicon nitride layer, a silicon oxynitride layer, a silicon oxide layer, a titanium oxide layer or an aluminum oxide layer. In some example embodiments, the first buffer film BF1 may be formed as a multilayer in which a plurality of layers selected from a silicon nitride layer, a silicon oxynitride layer, a silicon oxide layer, a titanium oxide layer and an aluminum oxide layer are alternately stacked.

An active layer including a channel region TCH, a source region TS, and a drain region TD of the thin film transistor TFT may be located on the first buffer film BF1. The active layer may include polycrystalline silicon, monocrystalline silicon, low-temperature polycrystalline silicon, amorphous silicon, or an oxide semiconductor material. When the active layer includes polycrystalline silicon or an oxide semiconductor material, the source region TS and the drain region TD of the active layer may be conductive regions doped with ions or impurities and having conductivity.

The gate insulating film 130 may be located on the active layer of the thin film transistor TFT. The gate insulating film 130 may be formed as or include an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of the capacitor Cst, and scan lines may be located on the gate insulating film 130. The gate electrode TG of the thin film transistor TFT may overlap the channel region TCH in the third direction DR3. The first gate metal layer may be formed as a single layer or multiple layers containing any one of molybdenum (Mo), aluminum (Al), chromium (Cr), gold (Au), titanium (Ti), nickel (Ni), neodymium (Nd), copper (Cu), or an alloy thereof.

A first interlayer insulating film 141 may be located on the first gate metal layer. The first interlayer insulating film 141 may be formed as an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including a second capacitor electrode CAE2 of the capacitor Cst may be located on the first interlayer insulating film 141. The second capacitor electrode CAE2 may overlap the first capacitor electrode CAE1 in the third direction DR3. Therefore, the capacitor Cst may be formed by the first capacitor electrode CAE1, the second capacitor electrode CAE2, and an inorganic insulating dielectric film (e.g., the first interlayer insulating film 141) located between the first capacitor electrode CAE1 and the second capacitor electrode CAE2 to serve as a dielectric film. The second gate metal layer may be formed as a single layer or multiple layers containing any one of molybdenum (Mo), aluminum (Al), chromium (Cr), gold (Au), titanium (Ti), nickel (Ni), neodymium (Nd), copper (Cu), or an alloy thereof.

A second interlayer insulating film 142 may be located on the second gate metal layer. The second interlayer insulating film 142 may be formed as an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first data metal layer including a first connection electrode CE1 and the data lines may be located on the second interlayer insulating film 142. The first connection electrode CE1 may be connected to the drain region TD through a first contact hole CT1 penetrating the gate insulating film 130, the first interlayer insulating film 141, and the second interlayer insulating film 142. The first data metal layer may be formed as a single layer or multiple layers containing any one of molybdenum (Mo), aluminum (Al), chromium (Cr), gold (Au), titanium (Ti), nickel (Ni), neodymium (Nd), copper (Cu), or an alloy thereof.

A first organic film 160 for flattening the stepped portion due to the thin film transistors TFT may be located on the first connection electrode CE1. The first organic film 160 may be formed as or include an organic film such as acrylic resin, epoxy resin, phenolic resin, polyamide resin, polyimide resin or the like.

The second data metal layer including a second connection electrode CE2 may be located on the first organic film 160. The second data metal layer may be connected to the first connection electrode CE1 through a second contact hole CT2 penetrating the first organic film 160. The second data metal layer may be formed as a single layer or multiple layers containing any one of molybdenum (Mo), aluminum (Al), chromium (Cr), gold (Au), titanium (Ti), nickel (Ni), neodymium (Nd), copper (Cu), or an alloy thereof.

A second organic film 180 may be located on the second connection electrode CE2. The second organic film 180 may be formed as an organic film such as acrylic resin, epoxy resin, phenolic resin, polyamide resin, polyimide resin or the like.

The light emitting element layer EML is located on the thin film transistor layer TFTL. The light emitting element layer EML may include light emitting elements LE and a bank 190.

Each of the light emitting elements LE may include a pixel electrode 171, a light emitting layer 172, and a common electrode 173. Each of the emission areas EA is an area in which the pixel electrode 171, the light emitting layer 172, and the common electrode 173 are sequentially stacked such that the holes from the pixel electrode 171 and the electrons from the common electrode 173 are combined with each other to emit light. In this case, the pixel electrode 171 may be an anode electrode, and the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be formed as a single layer or multiple layers including any one of molybdenum (Mo), aluminum (Al), chromium (Cr), gold (Au), titanium (Ti), nickel (Ni), neodymium (Nd), copper (Cu), or an alloy thereof.

In a top emission structure that emits light toward the common electrode 173 with respect to the light emitting layer 172, the pixel electrode 171 may be formed as a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The bank 190 serves to define the emission areas EA of the pixels. For example, the bank 190 may be formed to expose a partial region of the pixel electrode 171 on the second organic film 180. The bank 190 may cover the edge of the pixel electrode 171. The bank 190 may be located in the third contact hole CT3. That is, the third contact hole CT3 may be filled with the bank 190. The bank 190 may be formed as or include an organic film such as acrylic resin, epoxy resin, phenolic resin, polyamide resin, polyimide resin or the like.

A spacer 191 may be located on the bank 190. The spacer 191 may serve to support a mask during a process of manufacturing the light emitting layer 172. The spacer 191 may be formed as or include an organic film such as acrylic resin, epoxy resin, phenolic resin, polyamide resin, polyimide resin or the like.

The light emitting layer 172 is formed on the pixel electrode 171. The light emitting layer 172 may include an organic material to emit light of a selected color. For example, the light emitting layer 172 may include a hole transporting layer, an organic material layer, and an electron transporting layer. The organic material layer may include a host and a dopant. The organic material layer may include a material that emits selected light and may be formed using a phosphorescent material or a fluorescent material.

The common electrode 173 is formed on the light emitting layer 172. The common electrode 173 may be formed to cover the light emitting layer 172. The common electrode 173 may be a common layer which is commonly formed in the emission areas EA1, EA2, EA3, and EA4. A capping layer may be formed on the common electrode 173.

In the top emission structure, the common electrode 173 may include a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode 173 includes a semi-transmissive conductive material, the light emission efficiency can be increased due to a micro-cavity effect.

The encapsulation layer ENC may be formed on the light emitting element layer EML. The encapsulation layer ENC may include at least one inorganic film TFE1 and TFE2 to reduce or prevent oxygen or moisture from permeating into the light emitting element layer EML. In addition, the encapsulation layer ENC may include at least one organic film to protect the light emitting element layer EML from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be located on the common electrode 173, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer or an aluminum oxide layer are alternately stacked. The encapsulation organic film TFE2 may be an organic film such as acrylic resin, epoxy resin, phenolic resin, polyamide resin, polyimide resin or the like.

The sensor electrode layer SENL is located on the encapsulation layer ENC. The sensor electrode layer SENL may include sensor electrodes TE and RE.

A second buffer film BF2 may be located on the encapsulation layer ENC. The second buffer film BF2 may include at least one inorganic film. For example, the second buffer film BF2 may be formed as multiple films in which one or more inorganic films of a silicon nitride layer, a silicon oxynitride layer, a silicon oxide layer, a titanium oxide layer or an aluminum oxide layer are alternately stacked. The second buffer film BF2 may be omitted.

First connection portions BE1 may be located on the second buffer film BF2. The first connection portions BE1 may be formed as a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

A first sensor insulating film TINS1 may be located on the first connection portions BE1. The first sensor insulating film TINS1 may be formed as or include an inorganic film, for example, a silicon nitride layer, a silicon oxynitride layer, a silicon oxide layer, a titanium oxide layer, or an aluminum oxide layer.

The sensor electrodes, that is, the driving electrodes TE and the sensing electrodes RE may be located on the first sensor insulating film TNIS1. In addition, dummy patterns may be located on the first sensor insulating film TNIS1. The driving electrodes TE, the sensing electrodes RE, and the dummy patterns do not overlap the emission areas EA. The driving electrodes TE, the sensing electrodes RE, and the dummy patterns may be formed as a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

The second sensor insulating film TINS2 may be located on the driving electrodes TE, the sensing electrodes RE, and the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may include acrylic resin, epoxy resin, phenolic resin, polyamide resin, or polyimide resin.

The polarizing film PF and the cover window CW have been described above with reference to FIGS. 5 and 6, and thus a description thereof will be omitted.

The display devices 10 according to example embodiments of the present disclosure are not limited to the display device 10 including the organic light emitting layer 172 shown in FIG. 7. For example, the display device 10 according to an example embodiment of the present disclosure may be a display device including an inorganic light emitting diode, a quantum dot light emitting diode, or the like.

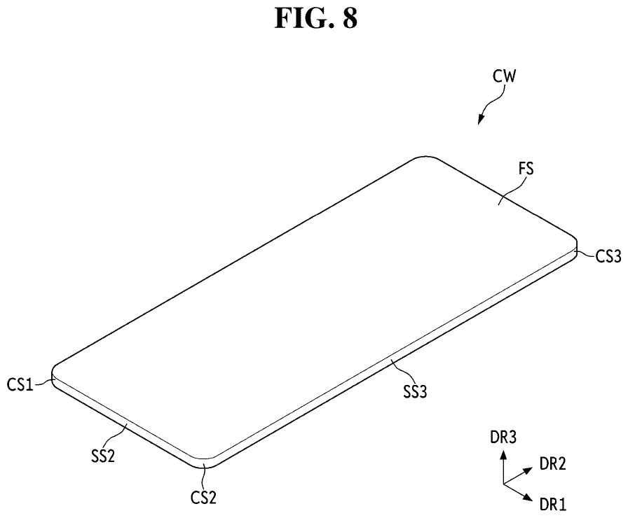

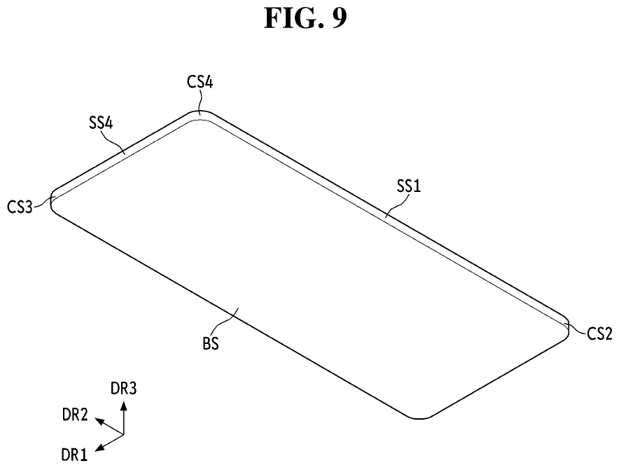

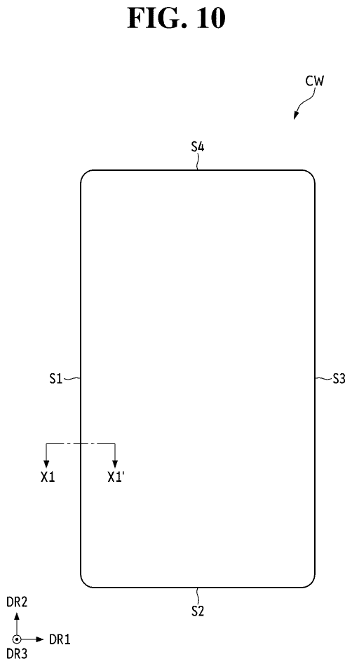

FIG. 8 is a front perspective view showing a cover window according to an example embodiment. FIG. 9 is a rear perspective view showing a cover window according to an example embodiment. FIG. 10 is a plan view showing a cover window according to an example embodiment.

Referring to FIGS. 8 to 10, the cover window CW includes a front surface FS, a rear surface BS, first to fourth side surfaces SS1, SS2, SS3, and SS4, and first to fourth corner surfaces CS1, CS2, CS3 and CS4.

The front surface FS may have a short side in the first direction DR1 and a long side in the second direction DR2. In the front surface FS, a corner where the short side in the first direction DR1 and the long side in the second direction DR2 meet may be rounded to have a selected radius of curvature or may be right-angled. The front surface FS may be formed flat or may include a curved portion having a selected radius of curvature.

The first side surface SS1 may extend from a first side S1 of the front surface FS, and the first side S1 of the front surface FS may be the left side of the front surface FS. The second side surface SS2 may extend from a second side S2 of the front surface FS, and the second side S2 of the front surface FS may be the lower side of the front surface FS. The third side surface SS3 may extend from a third side S3 of the front surface FS, and the third side S3 of the front surface FS may be the right side of the front surface FS. The fourth side surface SS4 may extend from a fourth side S4 of the front surface FS, and the fourth side S4 of the front surface FS may be the upper side of the front surface FS.

The first corner surface CS1 may be a corner side surface positioned between the first side surface SS1 and the second side surface SS2. The second corner surface CS2 may be a corner side surface positioned between the second side surface SS2 and the third side surface SS3. The third corner surface CS3 may be a corner side surface positioned between the third side surface SS3 and the fourth side surface SS4. The fourth corner surface CS4 may be a corner side surface positioned between the first side surface SS1 and the fourth side surface SS4.

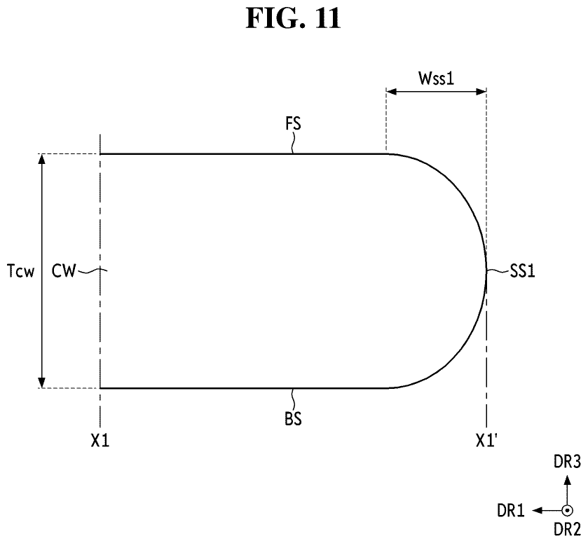

FIG. 11 is a cross-sectional view taken along line X1-X1′ of FIG. 10. FIG. 11 is a cross-sectional view illustrating the first side surface SS1 of the cover window CW. Because the shapes of the second to fourth side surfaces SS2, SS3, and SS4 of the cover window CW may be substantially the same except for directional differences, only the first side surface SS1 will be described.

Referring to FIG. 11, the first side surface SS1 of the cover window CW may have a curved shape having a selected radius of curvature. The radius of curvature of the first side surface SS1 of the cover window CW may be approximately 15 R to 25 R. As the radius of curvature of the first side surface SS1 of the cover window CW is 15 R to 25 R, the impact strength of the first side surface SS1 may be increased.

The radius of curvature of the first side surface SS1 may be the same or different at each point of the first side surface SS1. When the radius of curvature of the first side surface SS1 is different at each point of the first side surface SS1, the radius of curvature of the first side surface SS1 may be defined as an average value of the radii of curvature at the respective points of the first side surface SS1.

In an example embodiment, a width Wss1 (e.g., the length in the first direction DR1) of the first side surface SS1 of the cover window CW may be approximately 10 μm to 20 μm, and a thickness Tcw of the cover window CW may be approximately 30 μm to 60 μm.

Hereinafter, a method for manufacturing a cover window according to an example embodiment will be described.

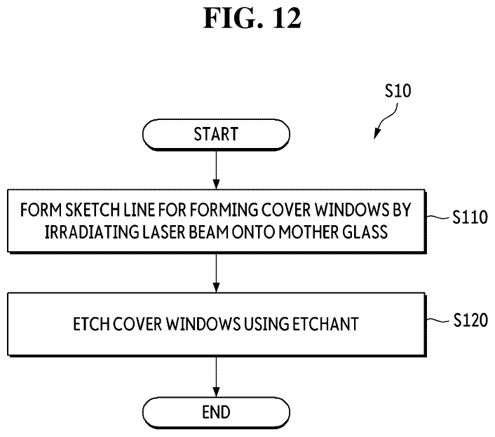

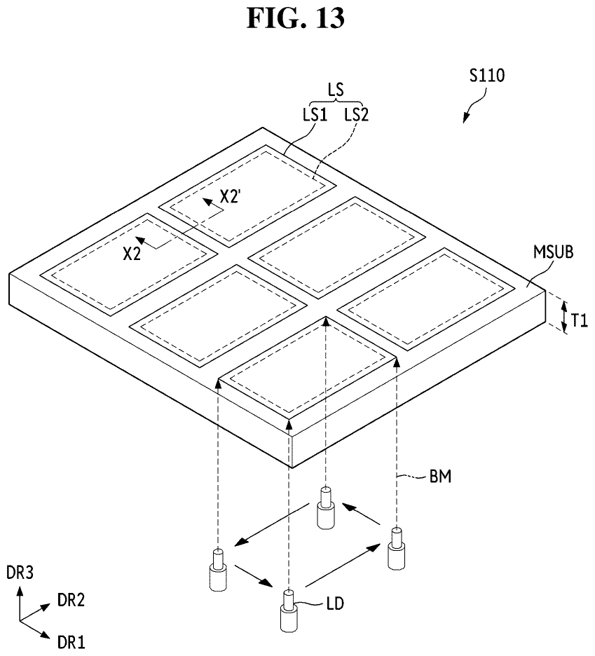

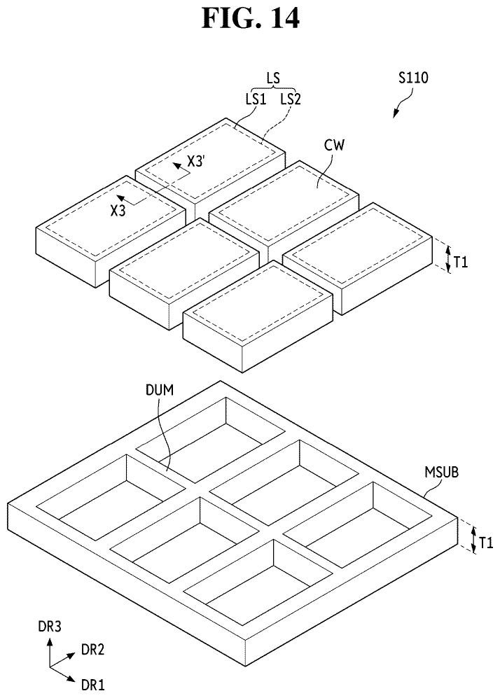

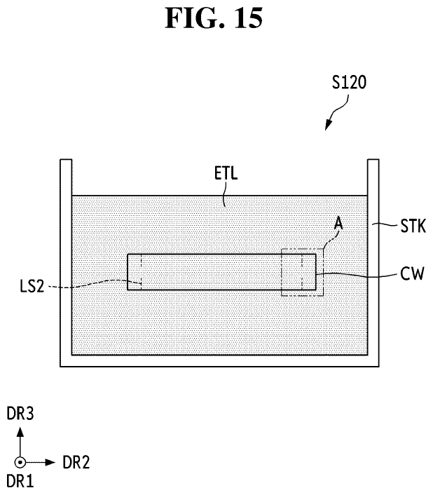

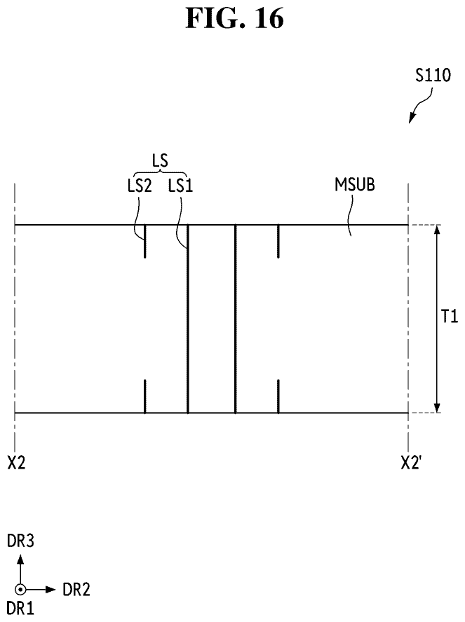

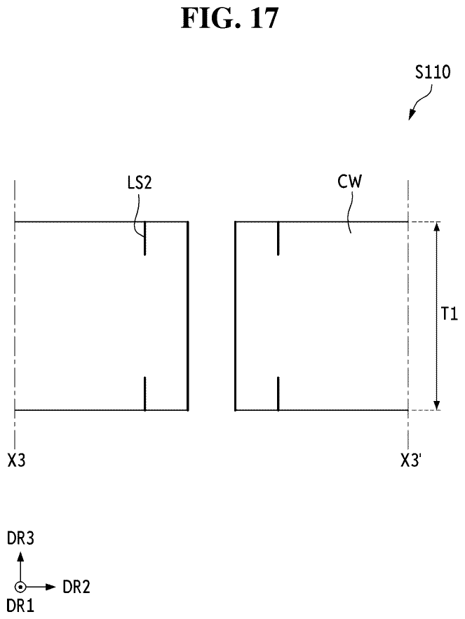

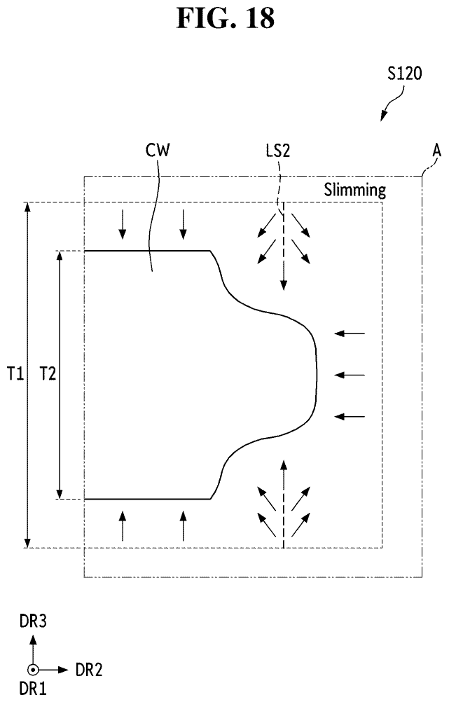

FIG. 12 is a flowchart showing a method for manufacturing a cover window according to an example embodiment. FIGS. 13 and 14 are perspective views showing operation S110 of FIG. 12. FIG. 15 is a cross-sectional view showing operation S120 of FIG. 12. FIGS. 16 and 17 are cross-sectional views showing operation S110 of FIG. 12. FIG. 18 is an enlarged view of area A of FIG. 15.

Referring to FIGS. 12 to 18, a cover window manufacturing method S10 according to an example embodiment may include forming a sketch line for forming a plurality of cover windows by irradiating a laser beam onto a mother glass (operation S110) and etching the plurality of cover windows using an etchant (operation S120).

First, as shown in FIGS. 13 and 16, a sketch line LS for forming the plurality of cover windows CW may be formed by irradiating a laser beam BM onto a mother glass MSUB (operation S110 of FIG. 12).

A laser processing apparatus LD may scan the laser beam BM along a selected imaginary line to form the plurality of cover windows CW. The laser processing apparatus LD may scan the laser beam BM along an imaginary line corresponding to the first side surface SS1 of any one of the plurality of cover windows CW. Then, the laser processing apparatus LD may scan the laser beam BM along imaginary lines corresponding to the second side surface SS2, the third side surface SS3, and the fourth side surface SS4 of the any one cover window CW. When the laser processing apparatus LD completes the scanning of the laser beam BM along an imaginary line corresponding to any one of the plurality of cover windows CW, the scanning of the laser beam BM along an imaginary line corresponding to another cover window CW may start. The laser processing apparatus LD may sequentially complete the scanning of the laser beam BM for all of the plurality of cover windows CW.

Then, as shown in FIGS. 14 and 17, the plurality of cover windows CW may be separated from the mother glass MSUB by the plurality of sketch lines LS formed by the scanning of the laser beam BM. In addition, the plurality of sketch lines LS formed by the scanning of the laser beam BM may be positioned inward of the side surfaces of the plurality of cover windows along the respective edges of the plurality of cover windows CW (operation S110 of FIG. 12).

For example, the plurality of sketch lines LS may include a plurality of first sketch lines LS1 and a plurality of second sketch lines LS2.

The plurality of first sketch lines LS1 are cutting lines for separating the plurality of cover windows CW from the mother glass MSUB. The plurality of first sketch lines LS1 may have a straight-line shape, such as a 1-shape or I-shape, extending in the third direction DR3 in a cross-sectional view taken along a plane defined by the second direction DR2 and the third direction DR3 or a plane defined by the first direction DR1 and the third direction DR3.

The plurality of second sketch lines LS2 may be partial cutting lines for forming the side surfaces SS1, SS2, SS3, and SS4 of the plurality of cover windows CW to have a selected radius of curvature. For example, the plurality of second sketch lines LS2 may not be cutting lines that completely separate the mother glass MSUB or the plurality of cover windows CW, but may be processing lines that provide a path through which an etchant ETL can penetrate so as to form the shapes of the first to fourth side surfaces SS1, SS2, SS3, and SS4.

The plurality of second sketch lines LS2 may be spaced apart from the plurality of first sketch lines LS1 in the first direction DR1 or the second direction DR2. The plurality of second sketch lines LS2 may have a straight-line shape, such as a 1-shape or I-shape, extending in the third direction DR3 in a cross-sectional view taken along a plane defined by the second direction DR2 and the third direction DR3 or a plane defined by the first direction DR1 and the third direction DR3. The plurality of second sketch lines LS2 may have a half-line (or dotted-line) shape extending along the third direction DR3 from the top and bottom surfaces of the mother glass MSUB or the cover window CW in the inward direction of the mother glass MSUB or the cover window CW with respect to a corresponding one of the plurality of first sketch lines LS1.

Among the plurality of second sketch lines LS2, the second sketch line LS2 extending from the top surface of the mother glass MSUB or the cover window CW may be spaced apart in the third direction DR3 from the second sketch line LS2 extending from the bottom surface of the mother glass MSUB or the cover window CW. That is, the second sketch line LS2 may not completely penetrate the interior of the mother glass MSUB or the cover window CW but may only partially penetrate in the inward direction from the top and bottom surfaces.

Thus, the plurality of cover windows CW may be separated from the mother glass MSUB by the plurality of first sketch lines LS1, and the plurality of second sketch lines LS2 may be formed along the respective edges of the plurality of cover windows CW.

In some example embodiments, the plurality of first sketch lines LS1 and the plurality of second sketch lines LS2 may be simultaneously formed by the scanning of the laser beam BM of the laser processing apparatus LD. For example, the laser processing apparatus LD may scan the mother glass MSUB while outputting the laser beam BM multiple times, and the plurality of first sketch lines LS1 and the plurality of second sketch lines LS2 may be formed simultaneously in each instance of the laser beam BM.

Next, as shown in FIGS. 15 and 18, the plurality of cover windows CW may be etched using the etchant ETL (operation S120 of FIG. 12).

The plurality of cover windows CW in which the second sketch lines LS2 are formed may be etched by the etchant ETL. For example, the cover window CW may be immersed in the etchant ETL stored in an etchant storage tank STK.

Accordingly, the thickness of the cover window CW may be reduced through slimming from a first thickness T1 to a second thickness T2. The thickness of the cover window CW may be reduced by approximately 20% to 50%.

In addition, the etchant ETL may penetrate the second sketch line LS2, allowing etching to proceed not only in the thickness direction of the cover window CW (e.g., the third direction DR3) but also in the direction toward the cover window CW from the second sketch line LS2 due to the isotropy of the etchant ETL. Therefore, the first to fourth side surfaces SS1, SS2, SS3, and SS4 of the cover window CW may be formed along the shape of the second sketch line LS2.

Each of the plurality of cover windows CW may be formed to have the side surfaces SS1, SS2, SS3, and SS4 with a selected curved shape only through a laser process using the laser processing apparatus LD and an etching process using the etchant ETL. Therefore, when manufacturing the plurality of cover windows CW, defects such as wedges or chipping caused by the CNC process may be reduced or prevented, thereby reducing manufacturing cost.

Hereinafter, a cover window manufacturing method S10 according to another example embodiment will be described, in which each of the plurality of cover windows CW is formed to have the side surfaces SS1, SS2, SS3, and SS4 with a curved shape having a selected radius of curvature, as described with reference to FIG. 11, and the like.

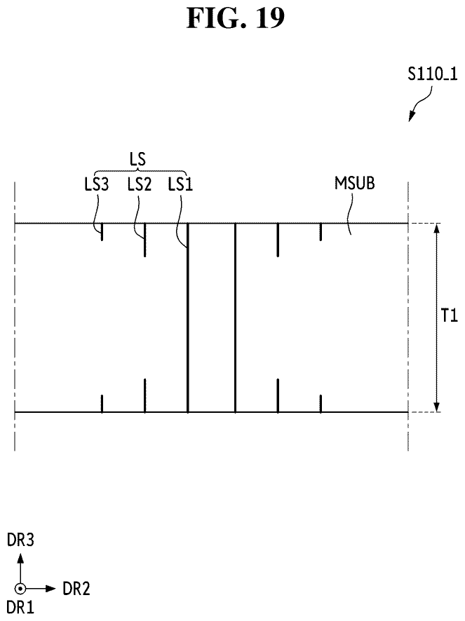

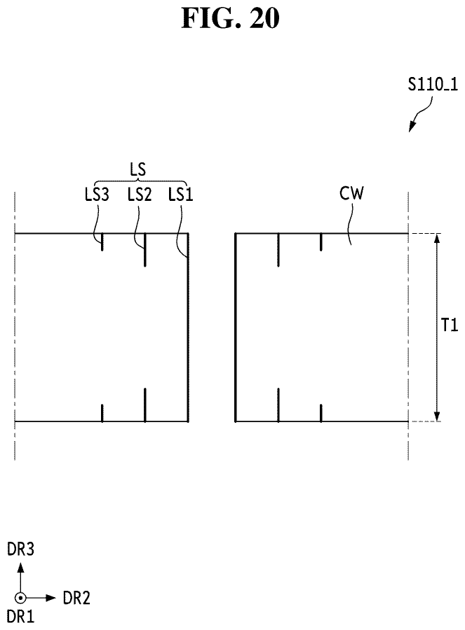

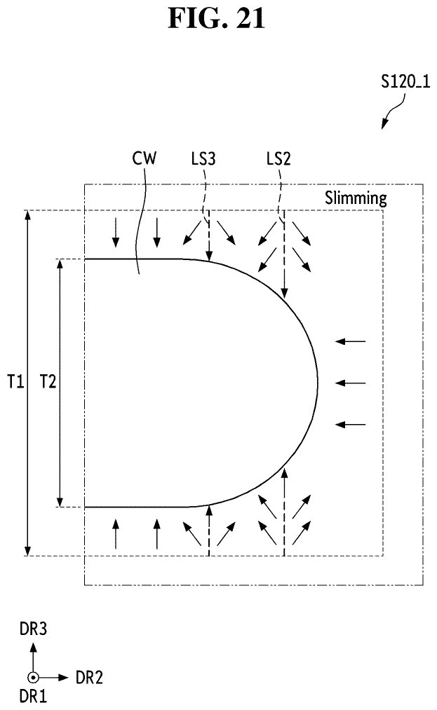

FIGS. 19 and 20 are cross-sectional views illustrating operation S110 of a cover window manufacturing method according to another example embodiment. FIG. 21 is a cross-sectional view illustrating operation S120 of a cover window manufacturing method according to another example embodiment.

Referring to FIGS. 19 to 21 in addition to FIG. 12, the cover window manufacturing method S10 according to another example embodiment differs from the cover window manufacturing method S10 according to the example embodiment described with reference to FIG. 16 and the like, in that the another example embodiment further includes a third sketch line LS3.

For example, the cover window manufacturing method S10 according to another example embodiment may include forming sketch lines for forming a plurality of cover windows by irradiating a laser beam onto a mother glass (operation S110) and etching the plurality of cover windows using an etchant (operation S120).

The plurality of sketch lines LS may include the plurality of first sketch lines LS1, the plurality of second sketch lines LS2, and the plurality of third sketch lines LS3.

Descriptions of the plurality of first sketch lines LS1 and the plurality of second sketch lines LS2 are the same as described above, and thus will be omitted.

The plurality of third sketch lines LS3, together with the plurality of second sketch lines LS2, may be partial cutting lines for forming the side surfaces SS1, SS2, SS3, and SS4 of the plurality of cover windows CW to have a selected radius of curvature. For example, the plurality of third sketch lines LS3 may not be cutting lines that completely separate the mother glass MSUB or the plurality of cover windows CW, but may be processing lines that provide a path through which the etchant ETL can penetrate so as to form the shapes of the first to fourth side surfaces SS1, SS2, SS3, and SS4.

The plurality of third sketch lines LS3 may be spaced apart from the plurality of second sketch lines LS2 in the first direction DR1 or the second direction DR2. For example, the plurality of third sketch lines LS3 may be positioned on the opposite side of the plurality of first sketch lines LS1 with the plurality of second sketch lines LS2 interposed between the plurality of third sketch lines LS3 and the plurality of first sketch lines LS1. The plurality of third sketch lines LS3 may have a straight-line shape, such as 1-shape or I-shape, extending in the third direction DR3 in a cross-sectional view taken along a plane defined by the second direction DR2 and the third direction DR3 or a plane defined by the first direction DR1 and the third direction DR3. The plurality of third sketch lines LS3 may have a half-line (e.g., dotted line) shape extending from the top and bottom surfaces of the mother glass MSUB or the cover window CW in the inward direction of the mother glass MSUB or the cover window CW along the third direction DR3.

Among the plurality of third sketch lines LS3, the third sketch line LS3 extending from the top surface of the mother glass MSUB or the cover window CW may be spaced apart in the third direction DR3 from the third sketch line LS3 extending from the bottom surface of the mother glass MSUB or the cover window CW. That is, the third sketch line LS3 may not completely penetrate the interior of the mother glass MSUB or the cover window CW but may only partially penetrate in the inward direction from the top and bottom surfaces.

In some example embodiments, a depth to which each of the plurality of third sketch lines LS3 penetrates the mother glass MSUB or the cover window CW may be smaller than a depth to which each of the plurality of second sketch lines LS2 penetrates the mother glass MSUB or the cover window CW.

Thus, the plurality of cover windows CW may be separated from the mother glass MSUB by the plurality of first sketch lines LS1, and the plurality of second sketch lines LS2 and the plurality of third sketch lines LS3 may be formed along the respective edges of the plurality of cover windows CW.

In some example embodiments, the plurality of first sketch lines LS1, the plurality of second sketch lines LS2, and the plurality of third sketch lines LS3 may be simultaneously formed by the scanning of the laser beam BM of the laser processing apparatus LD. For example, the laser processing apparatus LD may scan the mother glass MSUB while outputting the laser beam BM multiple times, and the plurality of first sketch lines LS1, the plurality of second sketch lines LS2, and the plurality of third sketch lines LS3 may be simultaneously formed in each instance of the laser beam BM.

The plurality of cover windows CW in which the second sketch lines LS2 and the third sketch lines LS3 are formed may be etched by the etchant ETL. For example, the cover window CW may be immersed in the etchant ETL stored in the etchant storage tank STK.

Accordingly, the thickness of the cover window CW may be reduced through slimming from the first thickness T1 to the second thickness T2. The thickness of the cover window CW may be reduced by approximately 20% to 50%.

In addition, the etchant ETL may penetrate the second sketch line LS2 and the third sketch line LS3, allowing etching to proceed not only in the thickness direction of the cover window CW (e.g., the third direction DR3) but also in the direction toward the cover window CW from the second sketch line LS2 and in the direction toward the cover window CW from the third sketch line LS3 due to the isotropy of the etchant ETL. Therefore, the first to fourth side surfaces SS1, SS2, SS3, and SS4 of the cover window CW may be formed along the shapes of the second sketch line LS2 and the third sketch line LS3.

In the above, the cover window manufacturing method S10 has been described with two or three sketch lines LS as examples, but the number of sketch lines LS for shape processing may be modified in various ways, except for the first sketch line LS1 for separating the cover window CW. As the number of sketch lines LS for shape processing increases, the first to fourth side surfaces SS1, SS2, SS3, and SS4 of the cover window CW may become closer to a curved shape having a selected radius of curvature.

Hereinafter, an apparatus for manufacturing a cover window according to an example embodiment will be described.

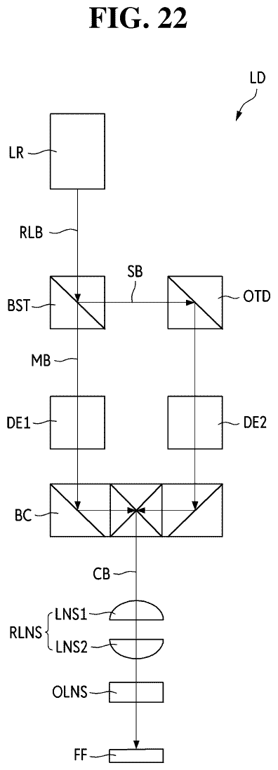

FIG. 22 is a schematic side view illustrating a cover window manufacturing apparatus according to an example embodiment.

Referring to FIG. 22, the laser processing apparatus LD (or the cover window manufacturing apparatus) according to an example embodiment may be an apparatus for manufacturing the cover window CW. For example, the laser processing apparatus LD may form the sketch line LS for forming the cover window CW from the mother glass MSUB by using the laser beam BM.

The laser processing apparatus LD according to an example embodiment may include a light source LR, a beam splitter BST, a first phase mask DE1, a second phase mask DE2, an optical delay OTD, a beam combiner BC, a relay lens RLNS, and an objective lens OLNS.

The light source LR may be a variety of known laser generating devices. The light source LR may emit a raw laser beam RLB. The light source LR may continuously or discontinuously emit the raw laser beam RLB. The light source LR may output the raw laser beam RLB of a single pulse or the raw laser beam RLB of a burst pulse including a plurality of pulses.

The light source LR may adjust the pulse duration, burst pulse, pulse energy, repetition rate, and/or the like of the raw laser beam RLB. For example, the pulse duration of the raw laser beam RLB may be approximately 300 femtoseconds (fs) to 10 picoseconds (ps). The repetition rate of the raw laser beam RLB may be approximately 10 kHz to 1,000 kHz. When the light source LR outputs the raw laser beam RLB of a burst pulse, the burst pulse of the raw laser beam RLB may be approximately 2 to 5 pulses.

Various laser beams may be used as the raw laser beam RLB according to an example embodiment, but the raw laser beam RLB may have a wavelength band of approximately 300 nm to 2 μm. For example, the raw laser beam RLB may be an infrared Gaussian beam having a wavelength band of approximately 800 nm to 1,100 nm.

The beam splitter BST may split the raw laser beam RLB incident from the light source LR into a main beam MB and a sub-beam SB. In some example embodiments, the beam splitter BST may be an optical element that reflects a portion of light and transmits another portion of the light. For example, the beam splitter BST may include a semi-transmissive mirror or a diffractive optical element (DOE).

In the cover window manufacturing method S10 described with reference to FIG. 12 and the like, the main beam MB may form the first sketch line LS1 (see FIG. 13), and the sub-beam SB may form the second sketch line LS2 (and the third sketch line LS3).

In some example embodiments, the beam splitter BST may adjust the polarization states of the main beam MB and the sub-beam SB. For example, the beam splitter BST may set the extension directions of the polarization axes of the main beam MB and the sub-beam SB or the angles of the polarization axes with respect to a specific direction to be different from each other. In one example, the polarization axes of the main beam MB and the sub-beam SB may be converted to be orthogonal to each other by the beam splitter BST.

In the drawing, the raw laser beam RLB is illustrated as being split into two beams (e.g., the main beam MB and the sub-beam SB) by the beam splitter BST but is not limited thereto. The number of beams formed by splitting the raw laser beam RLB using the beam splitter BST may be variously modified. For example, the raw laser beam RLB may be split into one main beam MB and two or more sub-beams SB by the beam splitter BST.

In the laser processing apparatus LD according to the present example embodiment, the paths of the main beam MB and the sub-beam SB may be spatially separated by the beam splitter BST. Here, spatial separation includes not only a case where the paths of the main beam MB and the sub-beam SB do not completely overlap, as illustrated in the drawing, but also a case where the main beam MB and the sub-beam SB travel along the same path with different vibration directions due to differences in the angles of their polarization axes.

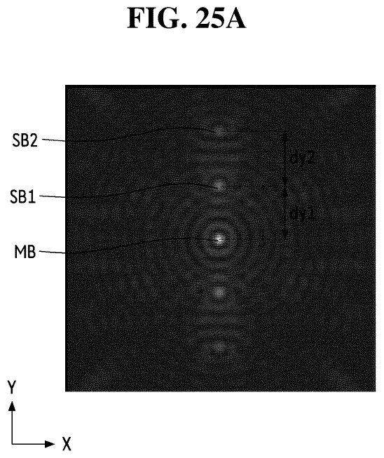

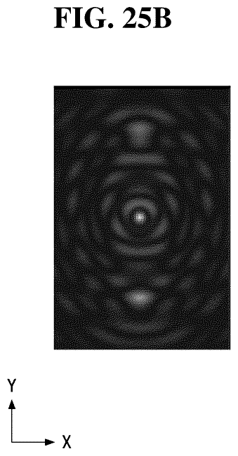

The paths of the main beam MB and the sub-beam SB may be spatially separated by the beam splitter BST and incident on the first phase mask DE1 and the second phase mask DE2, respectively, thereby allowing the shape and imaging position of each of the main beam MB and the sub-beam SB ultimately incident on a focal plane FF to be adjusted. The shape and imaging position of the main beam MB and the sub-beam SB will be described later with reference to FIG. 25 and the like.

In addition, by spatially separating the paths of the main beam MB and the sub-beam SB through the beam splitter BST, diffraction interference between the main beam MB and the sub-beam SB may be reduced or minimized when they are diffracted by the first phase mask DE1 and the second phase mask DE2, respectively.

The first phase mask DE1 may be positioned on the path of the main beam MB between the beam splitter BST and the beam combiner BC. The first phase mask DE1 may be an optical diffraction element for converting the shape of the incident main beam MB. For example, the main beam MB may be converted into a Bessel beam by the first phase mask DE1. In some example embodiments, the first phase mask DE1 may be a diffractive optical element (DOE) with a fixed diffraction pattern or a spatial light modulator (SLM) capable of actively changing diffraction patterns.

The second phase mask DE2 may be positioned on the path of the sub-beam SB between the beam splitter BST and the beam combiner BC. The second phase mask DE2 may be an optical diffraction element for converting the shape of the incident sub-beam SB. For example, the sub-beam SB may be converted into a Bessel beam by the second phase mask DE2. In some example embodiments, the second phase mask DE2 may be a diffractive optical element (DOE) with a fixed diffraction pattern or a spatial light modulator (SLM) capable of actively changing diffraction patterns.

In the drawing, the laser processing apparatus LD is illustrated as including two phase masks, but the number of phase masks is not limited thereto. The number of phase masks included in the laser processing apparatus LD may vary depending on the number of the main beam MB and the sub-beam SB. For example, the number of phase masks included in the laser processing apparatus LD may be the same as the number of the main beam MB and the sub-beam SB.

The laser processing apparatus LD according to the present example embodiment may include phase masks involved in the diffraction of the main beam MB and the sub-beam SB, respectively, thereby reducing or minimizing diffraction interference between the main beam MB and the sub-beam SB when the main beam MB and the sub-beam SB are diffracted by the first phase mask DE1 and the second phase mask DE2, respectively.

The optical delay OTD may be positioned on the path of the sub-beam SB between the beam splitter BST and the second phase mask DE2. However, example embodiments of the present disclosure are not limited thereto, and the optical delay OTD may be positioned on the path of the main beam MB. For example, the optical delay OTD may be positioned on the path of the main beam MB between the beam splitter BST and the first phase mask DE1.

The optical delay OTD may be positioned on the path of any one of the main beam MB or the sub-beam SB to adjust the path length of any one of the main beam MB or the sub-beam SB, thereby delaying the arrival time. For example, as shown in FIG. 22, the optical delay OTD may adjust the path length of the sub-beam SB to delay the arrival time of the sub-beam SB such that the sub-beam SB arrives at the beam combiner BC later than the main beam MB. In some example embodiments, the optical delay OTD may include a reflective mirror or an optical fiber loop.

In an example embodiment, the time delay range of the optical delay OTD may be approximately 1 ps to 10 ps. For example, one of the main beam MB or the sub-beam SB may arrive at the beam combiner BC approximately 1 ps to 10 ps later than the other.

In the laser processing apparatus LD according to the present example embodiment, the main beam MB and the sub beam SB may be temporally separated by delaying the arrival time of any one of the main beam MB or the sub beam SB using the optical delay OTD. Accordingly, when the main beam MB and the sub-beam SB are diffracted by the first phase mask DE1 and the second phase mask DE2, respectively, diffraction interference between the main beam MB and the sub-beam SB may be reduced or minimized.

The beam combiner BC may be positioned between the first and second phase masks DE1 and DE2 and the relay lens RLNS (or the objective lens OLNS). The beam combiner BC may combine the main beam MB and the sub-beam SB to form a single combined beam CB. In some example embodiments, the beam combiner BC may include a semi-transparent mirror, a prism, or a diffractive optical element (DOE).

Even when the main beam MB and the sub-beam SB are combined into the single combined beam CB, as described above, because the main beam MB and the sub-beam SB are spatially and temporally separated, the beams may be imaged at different positions on the focal plane FF.

The relay lens RLNS may be positioned between the beam combiner BC and the objective lens OLNS. The relay lens RLNS may transmit light at a ratio of n (where n is a positive integer):1 or 1:n. For example, the relay lens RLNS may transmit the combined beam CB incident from the beam combiner BC to the objective lens OLNS at a ratio of n:1 or 1:n. In some example embodiments, the relay lens RLNS may be omitted.

The relay lens RLNS may include a first lens LNS1 and a second lens LNS2. The first lens LNS1 may be positioned adjacent to the beam combiner BC, and the second lens LNS2 may be positioned adjacent to the objective lens OLNS.

In some example embodiments, the first lens LNS1 may be a convex lens that is convex toward the beam combiner BC, and the second lens LNS2 may be a convex lens that is convex toward the objective lens OLNS.

The objective lens OLNS may image the combined beam CB that has passed through the relay lens RLNS, at a selected distance. For example, the objective lens OLNS may image the combined beam CB that has passed through the relay lens RLNS on the focal plane FF.

In some example embodiments, the objective lens OLNS may have a relatively high numerical aperture (NA). For example, the numerical aperture of the objective lens OLNS may be approximately 0.4 or more.

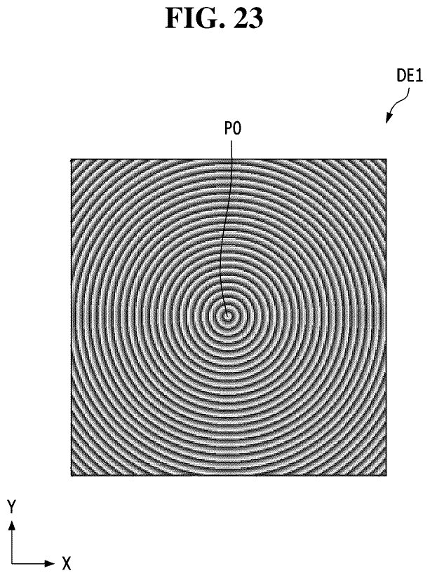

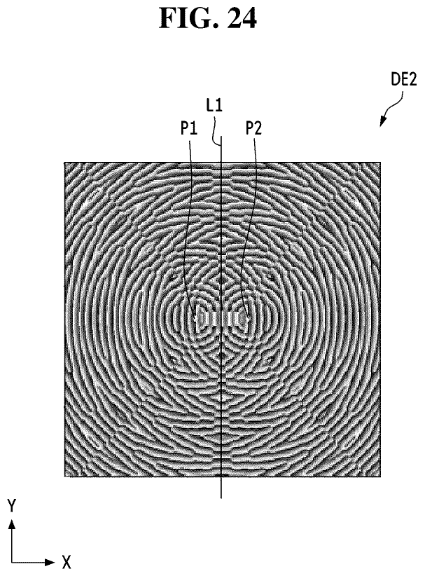

FIG. 23 is a plan view showing a diffraction pattern of a first phase mask in an XY plane. FIG. 24 is a plan view showing a diffraction pattern of a second phase mask in an XY plane.

Referring to FIGS. 23 and 24, in order to form different shapes of the main beam MB and the sub-beam SB, the shapes of the first phase mask DE1 and the second phase mask DE2 may differ from each other.

As shown in FIG. 23, the first phase mask DE1 may include a phase modulation structure (or diffraction pattern) having radial arrangement with respect to a single center P0. For example, the first phase mask DE1 may include the phase modulation structure in the form of a plurality of concentric circles having the same single center P0. In the illustration of FIG. 23, the dark portions (black portions) represent the valley portions of the phase modulation structure, while the bright portions (white portions) represent the ridge portions of the phase modulation structure. The main beam MB may be incident on such a phase modulation structure and may be converted into a single relatively long line beam in a 1-shape or I-shape by diffraction and interference effects.

As shown in FIG. 24, the second phase mask DE2 may include a phase modulation structure (or diffraction pattern) having radial arrangement with respect to two or more centers P1 and P2. For example, the second phase mask DE2 may include a plurality of concentric circles having the same single first center P1, a plurality of concentric circles having the same single second center P2, and the phase modulation structure in which these concentric circles are symmetrically divided into left and right sides with respect to a reference line L1 extending along a Y-axis. In other words, a first group of concentric circles having the first center P1 and a second group of concentric circles having the second center P2 may be provided to be symmetric to each other with respect to a first straight line extending in one direction. In the illustration of FIG. 24, the dark portions (black portions) represent the valley portions of the phase modulation structure, while the bright portions (white portions) represent the ridge portions of the phase modulation structure. The relatively SB may be incident on such a phase modulation structure and may be converted into a dotted-line beam including a plurality of short spot beams in a 1-shape or I-shape by diffraction and interference effects.

The shapes of the main beam MB and the sub-beam SB converted by the first phase mask DE1 and the second phase mask DE2, respectively, will be described below with reference to FIG. 25 and the like. Hereinafter, a case where one main beam MB and two sub-beams SB are formed will be described by way of example.

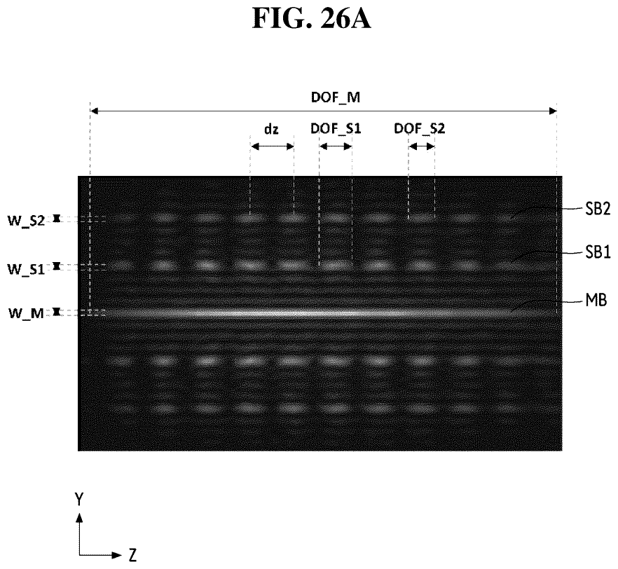

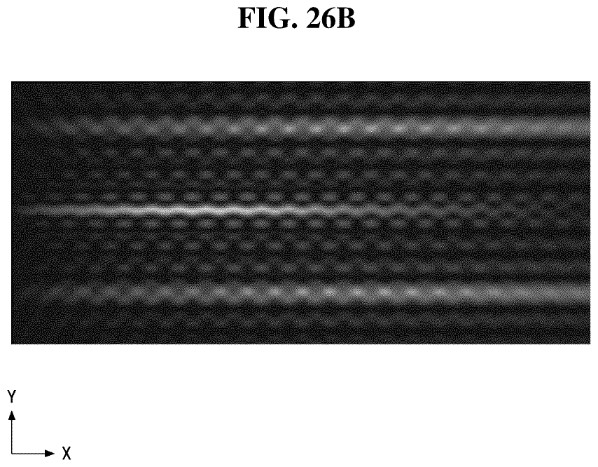

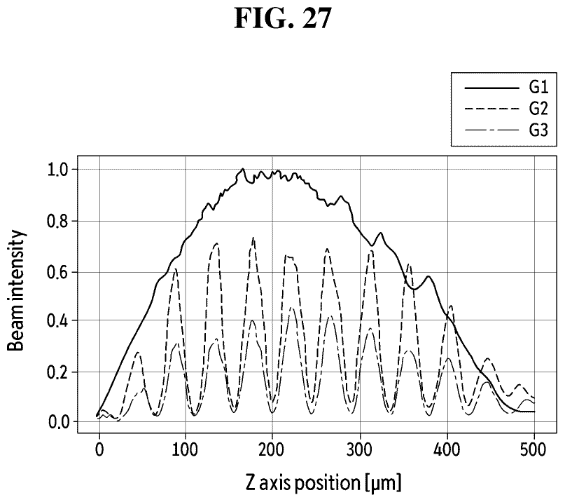

FIG. 25A is a photograph illustrating a two-dimensional shape of a main beam and sub-beams in an XY plane formed by a cover window manufacturing apparatus according to an example embodiment. FIG. 25B is a photograph illustrating a two-dimensional shape of a main beam and sub-beams in an XY plane formed by a cover window manufacturing apparatus according to a comparative example. FIG. 26A is a photograph illustrating a two-dimensional shape of a main beam and sub-beams in a YZ plane formed by a cover window manufacturing apparatus according to an example embodiment. FIG. 26B is a photograph illustrating a two-dimensional shape of a main beam and sub-beams in a YZ plane formed by a cover window manufacturing apparatus according to a comparative example. FIG. 27 is a graph illustrating the beam intensities of a main beam and sub-beams according to a Z-axis position.

The photographs shown in FIGS. 25A, 25B, 26A, and 26B illustrate the shapes of the respective beams on the focal plane FF (see FIG. 22).

Referring to FIGS. 25A, 25B, 26A, 26B, and 27, the main beam MB and sub-beams SB1 and SB2 formed by the cover window manufacturing apparatus may be spaced apart from each other in a Y-axis direction.

For example, as shown in FIG. 25A, the main beam MB and a first sub-beam SB1 may be spaced apart from each other by a first Y-axis distance dy1 in the Y-axis direction, and the first sub-beam SB1 and a second sub-beam SB2 may be spaced apart from each other by a second Y-axis distance dy2 in the Y-axis direction. In some example embodiments, the first Y-axis distance dy1 and the second Y-axis distance dy2 may each be in a range of about 5 μm to about 20 μm. The first Y-axis distance dy1 and the second Y-axis distance dy2 may be the same as or different from each other.

The main beam MB formed by the cover window manufacturing apparatus according to an example embodiment may be a single relatively long line beam in a 1-shape or I-shape extending in a Z-axis direction. In an example embodiment, a depth of focus DOF_M of the main beam MB may be approximately several hundred micrometers. The depth of focus DOF_M of the main beam MB is based on full width at half maximum (FWHM) values in the Z-axis direction of the beam intensities of the respective beams shown in FIG. 27.

The sub-beams SB1 and SB2 formed by the cover window manufacturing apparatus according to an example embodiment may be dotted-line beams including a plurality of short spot beams in a 1-shape or I-shape extending in the Z-axis direction. The plurality of spot beams included in each of the sub-beams SB1 and SB2 may be spaced apart from each other in the Z-axis direction. For example, the plurality of spot beams may be spaced apart from each other by a first interval dz (see FIG. 26A). The first interval dz refers to a distance between the centers of the plurality of spot beams in the Z-axis direction.

In an example embodiment, a depth of focus DOF_S1 of each of the plurality of spot beams of the first sub-beam SB1 and a depth of focus DOF_S2 of each of the plurality of spot beams of the second sub-beam SB2 may be approximately 20 μm or more. The depth of focus DOF_S1 of each of the plurality of spot beams of the first sub-beam SB1 and the depth of focus DOF_S2 of each of the plurality of spot beams of the second sub-beam SB2 are based on the full width at half maximum (FWHM) values in the Z-axis direction of the beam intensities of the respective beams shown in FIG. 27.

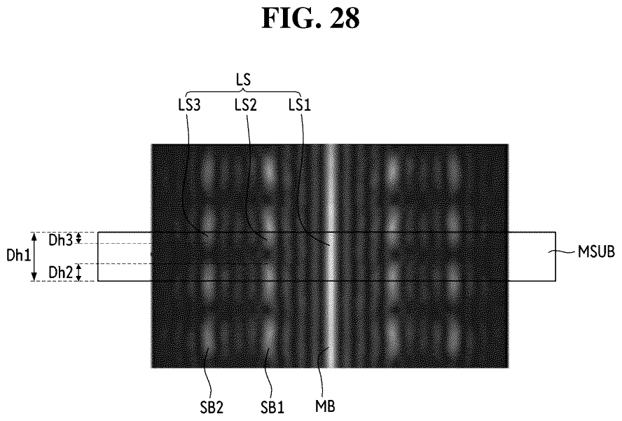

In some example embodiment, the depth of focus DOF_S1 of each of the plurality of spot beams of the first sub-beam SB1 and the depth of focus DOF_S2 of each of the plurality of spot beams of the second sub-beam SB2 may be less than half of the first interval dz. Accordingly, as will be described later with reference to FIG. 28, the plurality of spot beams may be positioned adjacent to the top and bottom surfaces of the mother glass MSUB but may not penetrate the mother glass MSUB in the same manner as the main beam MB.

A width W_M of the main beam MB in the Y-axis direction, a width W_S1 of the first sub-beam SB1 in the Y-axis direction, a width W_S2 of the second sub-beam SB2 in the Y-axis direction may be approximately 1 μm or less. The width W_M of the main beam MB in the Y-axis direction, the width W_S1 of the first sub-beam SB1 in the Y-axis direction, and the width W_S2 of the second sub-beam SB2 in the Y-axis direction are based on the full width at half maximum (FWHM) values in the Y-axis direction of the beam intensities of the respective beams.

In some example embodiments, the aspect ratios (AR) of the sub-beams SB1 and SB2 may be greater than 20. For example, the aspect ratios of the sub-beams SB1 and SB2 may be defined as the values of the depths of focus DOF_S1 and DOF_S2 of the sub-beams SB1 and SB2 with respect to the widths W_S1 and W_S2 of the sub-beams SB1 and SB2 in the Y-axis direction, respectively. Therefore, as described above, because the widths W_S1 and W_S2 of the sub-beams SB1 and SB2 in the Y-axis direction are approximately 1 μm or less, and the values of the depths of focus DOF_S1 and DOF_S2 of the sub-beams SB1 and SB2 are approximately 20 μm or more, the aspect ratios may be approximately 20 or more.

FIG. 27 illustrates graphs showing the beam intensities of the main beam MB and the sub-beams SB1 and SB2 according to their Z-axis positions. A first graph G1 represents the beam intensity of the main beam MB, a second graph G2 represents the beam intensity of the first sub-beam SB1, and a third graph G3 represents the beam intensity of the second sub-beam SB2.

As shown in FIG. 27, the beam intensities of the sub-beams SB1 and SB2 may be approximately 30% to 80% of the beam intensity of the main beam MB. In some example embodiments, the beam intensity of the second sub-beam SB2 may be less than that of the first sub-beam SB1. Here, the beam intensity of the main beam MB and the beam intensities of the sub-beams SB1 and SB2 each refer to an average value in the range of 0 μm to about 500 μm in the Z-axis direction.

FIGS. 25B and 26B illustrate the shapes of the main beam MB and the sub-beams SB formed by the laser processing apparatus LD according to a comparative example. The laser processing apparatus LD according to the comparative example forms the main beam MB and the sub-beams SB by using a single-phase mask rather than separate phase masks. In addition, unlike the laser processing apparatus LD according to an example embodiment, the laser processing apparatus LD according to the comparative example neither includes the beam splitter BST that adjusts a polarization state, nor the optical delay OTD that delays the arrival time of any one of the main beam MB or the sub-beams SB. Accordingly, when the main beam MB and the sub-beam SB are diffracted by a single-phase mask, they may interfere with each other. As a result, as shown in the drawings, the imaging positions of the main beam MB and the sub-beams SB may not be clearly separated, so the side shape of the cover window CW may not be precisely processed, and severe oscillations of each beam itself may deteriorate the surface roughness characteristics of the side surface of the cover window CW.

In contrast, in the laser processing apparatus LD according to an example embodiment, the main beam MB and the sub-beam SB may not only be individually diffracted by the first phase mask DE1 and the second phase mask DE2, respectively, but also be spatially separated by having different polarization states by the beam splitter BST or spatially separated by having entirely separate paths, and temporally separated by the optical delay OTD. Accordingly, interference between the main beam MB and the sub-beam SB may be reduced or minimized, thereby implementing a relatively high-quality processing laser.

FIG. 28 is a schematic diagram illustrating a sketch line formed on a mother glass by a main beam and sub-beams.

Referring to FIG. 28, the main beam MB may form the first sketch line LS1 on the mother glass MSUB, the first sub-beam SB1 may form the second sketch line LS2 on the mother glass MSUB, and the second sub-beam SB2 may form the third sketch line LS3 on the mother glass MSUB.

The main beam MB may be positioned across the entire thickness of the mother glass MSUB, from the top surface to the bottom surface of the mother glass MSUB. Accordingly, the first sketch line LS1 may completely penetrate the mother glass MSUB. Among the plurality of spot beams of each of the sub-beams SB1 and SB2, two spot beams adjacent to each other in the extension direction may be positioned adjacent to the top and bottom surfaces of the mother glass MSUB, respectively. Accordingly, the second sketch line LS2 and the third sketch line LS3 may not completely penetrate the mother glass MSUB.

A processing depth Dh1 of the mother glass MSUB by the main beam MB may be greater than a processing depth Dh2 of the mother glass MSUB by the first sub-beam SB1, and the processing depth Dh2 of the mother glass MSUB by the first sub-beam SB1 may be greater than a processing depth Dh3 of the mother glass MSUB by the second sub-beam SB2.

The display device 10 including the cover window CW according to the above-described example embodiments may be applied to various electronic devices 1. The electronic device 1 according to an example embodiment may include the display device 10 including the cover window CW described above, and may further include a module or a device having other additional functions in addition to the display device 10 including the cover window CW.

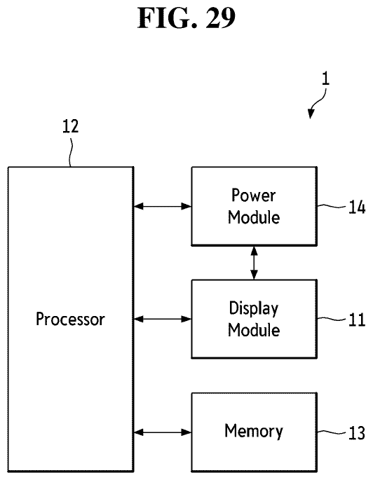

FIG. 29 is a block diagram of an electronic device according to an example embodiment.

Referring to FIG. 29, an electronic device 1 according to an example embodiment may include a display module 11, a processor 12, a memory 13, and a power module (or alternatively, power supply circuitry) 14.

The processor 12 may include at least one of a central processing unit (CPU), an application processor (AP), a graphic processing unit (GPU), a communication processor (CP), an image signal processor (ISP), or a controller.

The memory 13 may store data information desired for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power desired for the operation of the electronic device 1.

At least one of the components of the electronic device 1 described above may be included in the display device 10 according to the example embodiments described above. Further, some of individual modules functionally included in one module may be included in the display device 10 and some others may be provided separately from the display device 10. For example, the display device 10 may include the display module 11, and the processor 12, the memory 13, and the power module 14 may be provided in the form of other devices in the electronic device 1 other than the display device 10.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

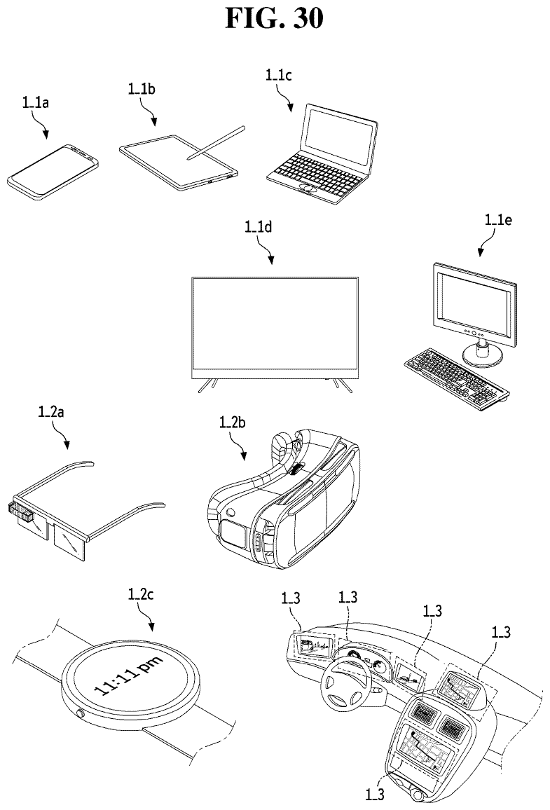

FIG. 30 is schematic views of electronic devices according to various example embodiments.

Referring to FIG. 30, various electronic devices 1 to which the display device 10 according to various example embodiments is applied may include not only an image display electronic device 1 such as a smartphone 1_1a, a tablet PC 1_1b, a laptop 1_1c, a TV 1_1d, and a desk monitor 1_1e, but also a wearable electronic device 1 including a display module, such as smart glasses 1_2a, a head mounted display 1_2b, a smart watch 1_2c, or the like, a vehicle electronic device 1_3 including a display module, such as a center fascia, and a dashboard of an automobile, a center information display (CID) placed on the dashboard, a room mirror display, or the like.

In concluding the detailed description, those skilled in the art will appreciate that many variations and modifications can be made to the disclosed example embodiments without substantially departing from the principles of the present disclosure. Therefore, the disclosed example embodiments of the inventive concepts are used in a generic and descriptive sense only and not for purposes of limitation.

What is claimed is:

1. An apparatus for manufacturing a cover window, comprising:
a light source configured to output a raw laser beam;
a beam splitter configured to split the raw laser beam into a main beam and at least one sub-beam;
a first phase mask configured to diffract the main beam to convert the main beam into a straight-line beam;
a second phase mask configured to diffract the sub-beam to convert the sub-beam into a dotted-line beam comprising a plurality of spot beams;
a beam combiner configured to combine the main beam and the sub-beam to form a single combined beam; and
an objective lens configured to focus the combined beam onto a focal plane,
wherein the beam splitter is configured to set extension directions of a polarization axis of the main beam and a polarization axis of the sub-beam to be different from each other.

2. The apparatus of claim 1, wherein the polarization axis of the main beam and the polarization axis of the sub-beam are orthogonal to each other.

3. The apparatus of claim 1, further comprising:
an optical delay being either between the beam splitter and the first phase mask or between the beam splitter and the second phase mask,
wherein the optical delay is configured to delay a time at which either the main beam or the sub-beam arrives at the beam combiner.

4. The apparatus of claim 3, wherein a time delay range of the optical delay is 1 ps to 10 ps.

5. The apparatus of claim 1, wherein
the first phase mask has a shape in which concentric circles having the same single center are arranged radially, and
the second phase mask has a shape in which concentric circles having at least two different centers are arranged radially.

6. The apparatus of claim 5, wherein
the at least two centers of the second phase mask comprise a first center and a second center, and
a first group of the concentric circles having the first center and a second group of the concentric circles having the second center are symmetric to each other with respect to a first straight line extending in one direction.

7. The apparatus of claim 1, wherein the main beam and the sub-beam, converted by the first phase mask and the second phase mask, respectively, have a Bessel beam shape.

8. The apparatus of claim 1, wherein the raw laser beam is a Gaussian beam.

9. The apparatus of claim 1, wherein a numerical aperture of the objective lens is 0.4 or more.

10. The apparatus of claim 1, wherein in the focal plane, the main beam and the sub-beam are spaced apart in a first direction.

11. The apparatus of claim 10, wherein in the focal plane, the main beam and the sub-beam extend in a second direction different from the first direction.

12. The apparatus of claim 11, wherein the sub-beam extends in the second direction and comprises a plurality of spot beams spaced apart from each other in the second direction.

13. The apparatus of claim 12, wherein in the second direction, a depth of focus of the main beam is greater than a depth of focus of each of the plurality of spot beams.

14. The apparatus of claim 13, wherein a width of the main beam in the first direction and a width of the sub-beam in the first direction are 1 μm or less.

15. The apparatus of claim 12, wherein
an aspect ratio of the sub-beam is defined as a depth of focus of the sub-beam in the second direction with respect to a width of the sub-beam in the first direction, and
the aspect ratio of the sub-beam is 20 or more.

16. The apparatus of claim 1, wherein a beam intensity of the sub-beam is 30% to 80% of a beam intensity of the main beam.

17. A method for manufacturing a cover window, comprising:
forming a sketch line for forming a cover window by irradiating a laser beam onto a mother glass; and
etching the cover window using an etchant,
wherein the sketch line comprises a first sketch line and a second sketch line positioned inside the first sketch line,
the cover window is separated from the mother glass by the first sketch line, and
the etchant penetrates in an inward direction of the cover window through the second sketch line.

18. The method of claim 17, wherein
the first sketch line penetrates the mother glass in a thickness direction,
the second sketch line extends from top and bottom surfaces of the mother glass in an inward direction of the mother glass, and
a length of the second sketch line is less than a thickness of the mother glass.

19. The method of claim 17, wherein
the sketch line comprises a third sketch line positioned inward from the second sketch line, and
a length of the third sketch line is less than a length of the second sketch line.

20. An electronic device comprising:
a display device comprising
a cover window manufactured by the apparatus of claim 1, and
a display panel located under the cover window;
a processor configured to provide a driving signal to the display device; and
a power module configured to supply power to the display device.
